(19) United States
(12) Patent Application Publication
(10) Pub. No.: US 2023/0213287 A1
(43) Pub. Date: Jul. 6, 2023

(54) TEMPERATURE-CONTROL BODY HOUSING, TEMPERATURE-CONTROL ARRANGEMENT, ELECTRIC DEVICE, AND USE THEREOF

(71) Applicant: Cloud & Heat Technologies GmbH, Dresden (DE)

(72) Inventors: Jens Struckmeier, Dresden (DE); Ricardo Buder, Dresden (DE); Stephan Pampel, Dresden (DE); Lukas Friedenstab, Dresden (DE); Martin Steinigen, Dresden (DE); Holm Puder, Freiberg (DE); Conrad Wachter, Dresden (DE)

(21) Appl. No.: 17/906,810

(22) PCT Filed: Mar. 25, 2021
(86) PCT No.: PCT/EP2021/057664

§ 371 Date: Sep. 20, 2022

(30) Foreign Application Priority Data
Apr. 3, 2020 (DE) 10 2020 109 368.3

(51) Int. Cl. F28D 1/03; F28F 21/04; F28F 13/14; F28F 1/40; F28F 21/08; F28F 21/06; F28F 3/02; F28F 3/12; F28F 21/00

(52) U.S. Cl. CPC F28D 1/03; F28F 21/04; F28F 13/14; F28F 1/40; F28F 21/08; F28F 21/062; F28F 3/027; F28F 3/12; F28F 21/006; F28D 2021/0029

(57) ABSTRACT

A temperature control body housing includes a monolithic housing middle portion penetrated by one or more than one fluid canal, each fluid canal being completely bounded on four sides by respective walls monolithically connected to outer walls of the housing middle portion; a first housing end cap and a second housing end cap between which the housing middle portion is disposed; wherein the first housing end cap has a first fluid port and either the first housing end cap or the second housing end cap has a second fluid port, and wherein the first fluid port and the second fluid port are fluidly connected to each other by means of the one or more fluid channels.

### CROSS-REFERENCE TO RELATED APPLICATIONS

This is a national phase of PCT Application PCT/EP2021/057664, which was filed on Mar. 25, 2021, and which claims priority to German Application 10 2020 109 368.3, which was filed on Apr. 3, 2020, the entire contents of each of these are incorporated by reference herein.

### TECHNICAL FIELD

Various embodiments relate to a temperature control body housing, a temperature control assembly, an electrical device, and the use thereof.

### BACKGROUND

The heat transfer from a heat source to a surrounding cooling medium is primarily dependent on the temperature difference, the effective surface area and the flow velocity of the surrounding cooling medium. The task of a heat sink is to promote (e.g. enhance) this process and to conduct lost heat away from the heat source by thermal conduction and then to dissipate it to the surroundings by thermal radiation and convection.

The use of conventional heat sinks can be divided into two types of cooling, namely active cooling and passive cooling. In active cooling, a cooling fluid is supplied to the heat sink by technical means. If ambient air is not necessarily to be used as the cooling fluid, a self-contained cooling system is often provided in which the cooling fluid can circulate.

Heat sinks for such a self-contained cooling system conventionally have a chamber through which the cooling fluid, e.g. water, is passed. There are a number of different designs and concepts for providing the chamber. The greater the cooling capacity is to be, the more complex chamber shapes are required to maximize the heat transfer area and convective heat transfer. The more complex the chamber shape, the more manufacturing steps are required, which increases the manufacturing cost. Traditionally, a serpentine-shaped chamber is machined into a copper block. Traditionally, several holes in a copper block are connected to form a chamber and must be subsequently closed again.

Due to ever larger data centers or ever larger numbers of processors (or other components to be cooled), the number of heat sinks required is also increasing. Accordingly, the manufacturing price, cooling capacity, material availability, environmental compatibility, reliability, and assembly effort of the temperature control elements (e.g. heat sinks) are becoming increasingly important economic and ecological factors.

### BRIEF SUMMARY

In order to take this development into account, according to various embodiments, a temperature control body housing (e.g. heat sink housing) is provided, which can be manufactured at low cost, is easy to assemble, provides a high temperature control performance (e.g. cooling performance), has few components and thus requires fewer seals, and which is particularly robust.

Illustratively, it was recognized that these properties can be achieved by dividing the temperature control body housing into several functional components, each of which has as few complex shapes as possible and is accessible to low-cost manufacturing processes.

The temperature control body housing according to various embodiments has a housing middle portion that is shaped such that it can be manufactured monolithically. This reduces the number of components and thus the assembly costs and the places where seals are required. For example, the housing middle portion can be stranded. This makes it possible to manufacture the housing middle portion in large quantities quickly and inexpensively, while at the same time realizing a large heat transfer surface.

The temperature control body housing according to various embodiments further comprises two end caps (also referred to as housing end caps or end pieces), which can be placed on the front side of the housing middle portion to provide a closed chamber inside. The end caps are separate components from the housing middle portion, for example, and thus can be made of a cheaper material, e.g., adapted dominant material costs. This achieves great flexibility to minimize the manufacturing price without having to affect the housing middle portion and thus the temperature control performance (e.g., cooling performance). Likewise, the end caps can be replaced with little assembly effort. The end caps can also be prefabricated in different types according to a variety of circumstances, so that the temperature control body housing can be easily adapted to the installation situation by means of a suitable type. A cap mold as such is not very complex and can therefore be produced quickly and inexpensively in large quantities, e.g. from a material that is easy to process, such as a plastic.

### BRIEF DESCRIPTION OF THE DRAWINGS

FIGS. 1 to 10, 11A and 21 to 28, respectively, depict a temperature control body housing (e.g., heat sink housing) according to various embodiments in various views;

FIG. 11B depicts the characteristics of a temperature control body housing in a schematic diagram according to various embodiments;

FIG. 12 depicts a schematic side view or cross-sectional view of a temperature control arrangement according to various embodiments;

FIG. 13 depicts an electrical device (e.g. comprising one or more than one processor, one or more than one memory chip (e.g. RAM), one or more than one mosfet, and/or one or more than one coil) according to various embodiments in a schematic side view or cross-sectional view;

FIGS. 14A and 14B each depict a temperature control module (e.g. cooling arrangement/cooling body) in a schematic perspective view according to different embodiments;

FIGS. 15A and 15B, respectively, the same electrical device in different schematic views according to different embodiments; and

FIGS. 16A to 20 each depict a temperature control module according to different embodiments, e.g. FIGS. 16A to 17B depict detailed views of the embodiments according to FIGS. 15A and 15B.

### DETAILED DESCRIPTION

In the following detailed description, reference is made to the accompanying drawings which form part thereof and in which are shown, for illustrative purposes, specific embodiments in which the invention may be practiced. In this regard, directional terminology such as “top”, “bottom”, “front”, “rear”, “front”, “rear”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is understood that the features of the various exemplary embodiments described herein may be combined, unless otherwise specifically indicated. Therefore, the following detailed description is not to be construed in a limiting sense, and the scope of protection of the present invention is defined by the appended claims.

In the context of this description, the terms “connected”, “attached”, and “coupled” are used to describe both a direct and an indirect connection (e.g. a fluid-conducting connection, i.e. a connection capable of conducting fluid), a direct or indirect connection as well as a direct or indirect coupling. In the figures, identical or similar elements are given identical reference signs where appropriate.

According to various embodiments, the term “coupled” or “coupling” may be understood in the sense of a (e.g. mechanical, hydrostatic, thermal and/or electrical), e.g. direct or indirect, connection and/or interaction. For example, multiple elements may be coupled together along an interaction chain along which the interaction (e.g., a material) may be transmitted. For example, two coupled elements may exchange an interaction with each other, such as a mechanical, hydrostatic, thermal, and/or electrical interaction. According to various embodiments, “coupled” may be understood in the sense of a mechanical (e.g., bodily or physical) coupling, e.g., by means of direct physical contact. A coupling may be configured to transmit a mechanical interaction (e.g., force, torque, etc.).

A fluid conducting connection or coupling between two elements may allow the two elements to exchange a fluid (i.e., comprising or formed from a liquid substance and/or gaseous substance) with each other. The fluid-conducting coupling may optionally be sealed to the outside so that the exchange of the fluid is substantially lossless. For example, fluid supplied to one element of the two elements can thus be supplied to the other element of the two elements by means of the fluid conducting connection.

Herein, reference is made to the process of temperature controlling (e.g. tempering) a component, e.g. by extracting thermal energy (also referred to as heat or thermal energy) from the component (also referred to as cooling) and/or adding thermal energy (also referred to as heating). The temperature controlling may comprise actively providing, e.g. by using electrical energy, a heat flow towards and/or away from the component.

Various electrical components (also referred to as electrical components) absorb electrical power during operation and convert it partially or completely into thermal power (also referred to as heat source or electrothermal converter). To dissipate the thermal power released in the process, a so-called temperature control element is usually used. The temperature control element can, for example, have a fluid flowing through or around it, e.g. a housing through which the fluid flows. The fluid may have a lower temperature than the electrical component, so that a continuous heat flow is provided from the electrical component to the fluid. The fluid can absorb the thermal power and carry it away along the direction of flow. This process of heat absorption by a flowing fluid allows much thermal power to be removed within a small space.

Optionally, the fluid can be continuously replaced with new fluid so that the fluid itself does not need to be temperature controlled (e.g., cooled). Alternatively, the fluid can be reused, e.g. cyclically, by temperature controlling (e.g. cooling) the fluid itself so that the temperature controlled (e.g. cooled) fluid is fed back to the temperature control body (also referred to as a temperature control cycle).

If thermal power is extracted from the electrical component by means of the temperature control body (also referred to as cooling), the temperature control body herein is referred to as a heat sink, the temperature control body housing as a heat sink housing, the fluid as a cooling fluid, or the fluid canal as a cooling canal. When thermal power is supplied to the electrical component by means of the temperature control body (also referred to as heating), the temperature control body is referred to herein as the heating body, the temperature control body housing as the heating body housing, the fluid as the heating fluid, or the fluid canal as the heating canal. Reference is made herein to, among other things, a temperature control body housing as an exemplary temperature control body housing. It may be understood that what is described for the heat sink housing may apply by analogy to any type of temperature control body housing, for example, a radiator housing.

In the following, reference is made, among other things, to a processor as an example of an electronic component (electronic member) to be temperature controlled. What is described for the processor may apply by analogy to an electronic component of another type, e.g. a transistor (e.g. MOSFET, i.e. metal oxide semiconductor field effect transistor), e.g. a power transistor, a coil, a memory device (e.g. RAM, i.e. random access memory) or the like.

According to various embodiments, a device having a heat sink housing for cooling electronics (also referred to as an electrical component or as electrical components) is provided. Examples of electrical components include: servers, server systems, network technology, communication technology, power electronics, converter systems, and electric motors.

The term “monolithic” in the context of a body can be understood as meaning that the body is formed in one piece, i.e. is not joined or, in other words, is free of material bonds or other joints (such as welds, soldered seams or adhesive seams). A monolithic body may be formed as a whole, e.g. only by means of casting, cutting and/or forming but without a joining, e.g. joining machining steps, i.e. without adding material thereto. A monolithic body may have a substantially uniform material composition, i.e., any portions of the body are formed from the same material (e.g., in the same chemical configuration). In the context of a hollow body (e.g., a housing middle portion), “monolithic” may be understood to mean that each cavity (e.g., each fluid canal) of the body is bounded by walls that are a monolithic part of the body (i.e., are also monolithically connected to each other). A hollow body (also referred to as a hollow body) refers to a body that has one or more than one cavity.

For example, a monolithic housing middle portion may have two fluid canals adjacent to a cooling fin (e.g., providing a channel wall) that is a monolithic component of the housing middle portion. For example, a monolithic housing middle portion may have a plurality of fluid channels adjacent in pairs to the same fin that is a monolithic component of the housing middle portion.

Each fluid canal of the housing middle portion may illustratively be completely bounded on four sides by means of corresponding walls (also referred to as canal walls) or may be exposed only on opposite sides of the housing middle portion. The channel walls of the monolithic housing middle portion, which bound the fluid channel on the four sides, may be monolithically connected to the outer walls of the housing middle portion.

For example, a monolithic housing middle portion may have only surfaces (e.g., the surfaces of the channel walls and/or the outer walls of the housing middle portion) that are monolithically bonded together.

A monolithic housing middle portion may, for example, be a continuous block through which one or more fluid canals extend. The or each fluid canal of the housing middle portion may, for example, extend through the housing middle portion along a linear path.

The fluid canal may denote the cavity that receives the fluid. The fluid canal may be bounded by walls that are in contact with the fluid when the fluid is introduced into (e.g., flows through) the fluid canal.

The term “releasable” in the context of a connection can be understood to mean that the connection can be established and/or released again without destruction. This can be achieved, for example, by means of connecting elements (e.g. positive locking elements) which, on contact, produce a form-fit or force-fit connection (e.g. hook into one another or clamp against one another) or can be friction-lock connected to one another by means of a latch. What is described herein by way of example for a form-fit connection can also apply by analogy for a force-fit connection.

Injection molding (also referred to as die casting or injection molding process) can be understood as a primary molding process that is used, for example, in plastics processing. Injection molding involves using an injection molding machine to liquefy (or plasticize) the respective material and inject it into a mold, the injection mold, under pressure. The result of injection molding is an injection molded product.

The temperature control body housing may include or be formed from at least two (i.e., two or more than two), e.g., at least three (i.e., three or more than three), parts (also referred to as housing components). The at least three housing components may be, for example, horizontally arranged and/or interconnected (e.g., connected via a fluid). Examples of the at least three housing components comprise: one or more than one housing end cap; and one or more than one housing middle portion.

The temperature control body housing may be configured to have or permit fluid to flow through it (e.g., water flows through it) during operation.

Two or more than two housing components of the at least three housing components may optionally be materially bonded to each other, e.g., by means of welding (using welding technology), soldering (using soldering technology), or adhesion (using adhesion technology). For example, one or more than one housing end cap and the housing middle portion may be materially bonded to each other, e.g., by means of welding (by means of welding technology), soldering (by means of soldering technology), or adhesion (by means of adhesion technology).

Optionally, two or more than two housing components of the at least three housing components may be positively connected to each other, e.g. by means of screwing, riveting, interlocking, e.g. by means of interlocking elements (also referred to as latching elements), or by means of other positive locking elements. For example, one or more than one housing end cap and the housing middle portion may be positively interconnected, e.g., by means of screwing, riveting, interlocking, e.g., by means of interlocking elements (also referred to as latching elements). A latching element can, for example, have a projection that engages in a recess in the corresponding latching element.

One, two, or more than two housing components of the at least three housing components may each be monolithically formed. For example, the or each housing middle portion of the temperature control body housing may be monolithic. Alternatively or additionally, one or more than one housing end cap of the temperature control body housing may be monolithically formed.

According to various embodiments, the temperature control body housing may have exactly two housing end caps. This simplifies the construction and/or mounting of the temperature control body housing.

The temperature control body housing (e.g., the at least three housing components) may have a composite of metal and plastic or be formed therefrom.

The at least three housing components may include a housing middle portion (also referred to as a housing middle section) comprising or formed from a high thermal conductivity metal. The high thermal conductivity metal may comprise: Copper, aluminum, or alloys thereof. Alternatively or additionally, the housing middle portion may comprise or be formed from steel.

The metal and plastic of the temperature control body housing may be configured so that they differ in their coefficient of linear thermal expansion (of either material) by less than about 10%.

The temperature control body housing (e.g., one or more than one housing component) may have an adhesive edge that is textured. For example, the bonding edge may have a rough textured surface or a profiled surface. The adhesive edge may increase the surface area or contact area between the housing components so that an adhesive bond between them is more reliable and fluid-tight.

The temperature control body housing can be (e.g. two or more housing components can be) connected to each other by means of riveting or screwing.

The housing middle portion can be or is manufactured by means of an extrusion process.

The housing middle portion may have or be formed of two half-shells which, when joined together, form one or more than one fluid canal penetrating the housing middle portion. For example, the half-shells may be configured to mate together and/or provide as large a surface area as possible between the fluid and the temperature control body.

The large surface area can be or is created by means of fins (also called temperature controlling fins, e.g. cooling fins).

The half shells can be held against each other to absorb the compressive forces by means of bolts, which are glued or screwed together, for example.

The temperature control body housing or at least the housing middle portion can be set up symmetrically on both sides at the top and bottom, so that the electrical component can be mounted as a component to be temperature controlled (e.g., cooled) on both the top and bottom sides.

The temperature control body housing can have two or more housing components that penetrate each other when joined together. This increases the surface area or contact area between the housing components, which makes it easier, for example, to provide a bonded joint reliably and tightly for fluids.

The housing middle portion (also referred to as the temperature controlling, e.g., cooling, middle portion) may comprise or be formed from thermally conductive metal and/or have substantially one or more than one smooth cut edge (e.g., at the end faces).

The housing middle portion may have a profile or be formed therefrom. For example, the housing middle portion may be a hollow chamber profile and/or and substantially suitable for guiding a fluid.

The housing end cap(s) may be formed such that a hollow chamber is provided on one side having the cavities formed such that, at the desired flow rate, the flow distribution is adjusted to provide a substantially uniform flow.

The housing end cap(s) can be designed in such a way that a hollow chamber is provided on one side, which has the cavities designed in such a way that, at the desired flow rate, the flow distribution is adjusted in such a way that certain areas are flowed through more strongly and certain areas are flowed through less strongly, so that the temperature controlling performance (e.g. cooling capacity) over the surface can be adjusted in such a way that even an inhomogeneous heat release of the component to be temperature controlled (e.g. cooled) can be temperature controlled (e.g. cooled) in such a way that a substantially uniform heating of the fluid takes place and thus a substantially uniform heating of the heat sink as well as a substantially uniform temperature of the component to be cooled.

The maximum high temperature level can be achieved or optimized by means of e.g. the design of the temperature control module (e.g. by a maximum high heat transfer surface) and/or by means of e.g. a high thermal efficiency (e.g. with a targeted choice of materials the heat, which is absorbed by the component to be cooled by means of the fluid, remains in the fluid and is not emitted to the environment via e.g. surfaces of the temperature control module (e.g. convectively and/or by heat radiation)).

On the one hand, the maximum high temperature level means that recooling can be carried out more efficiently and also by means of free cooling (i.e. purely passive release of thermal energy to the environment) at higher outside temperatures. On the other hand, the maximum high temperature level enables waste heat to be used, for example for building heating, or the waste heat can be used as a driving force, for example of an absorption heat pump.

The housing middle portion may have or be formed from a profile having fluid channels that are substantially closed in two dimensions.

The housing end cap(s) can be designed in such a way that they can be connected to the fluid channels in such a way that a serpentine flow through the fluid channels is created. This flow inhibits a temperature gradient of the surface to be temperature controlled (e.g. cooled). The temperature gradient is inhibited, for example, by a pair of fluid channels providing a serpentine flow path (illustratively, one fluid channel of the pair of fluid channels represents the fluid forward flow and the other represents the fluid return flow). The serpentine flow path may or may not be provided by the total number of fluid channels.

The temperature control body housing may include a heat conduction substance (e.g., a pad, paste, adhesive, or liquid) of spatially varying thickness and/or spatially varying thermal conductivity.

The temperature control body housing may include a heat conduction substance which is configured to at least partially compensate for a temperature gradient created in the temperature control body housing in the flow direction, e.g., such that multiple components to be temperature controlled (e.g., cooled) experience substantially the same temperature level and temperature control performance (e.g., cooling performance).

To determine a thickness, arrangement and/or thermal conductivity of the heat conducting substance, thermal simulations can be used.

The housing end cap(s) can be screwed or riveted.

The housing middle portion may be arranged such that direct screwing into the housing middle portion (for connecting a housing end cap thereto) can be performed, e.g., without post-processing and/or by means of one or more than one self-tapping screw.

The housing middle portion can, for example, be designed by thermal simulation in such a way that a substantially uniform temperature control (e.g. cooling) takes place despite screwed structures.

The temperature control body housing can have one or more than one connection point (between two housing components), which is configured to be optionally provided with or without a seal (or sealing material). For example, turbulators can be introduced. Alternatively or additionally, a defined surface structure/roughness can specifically achieve that the heat transfer in the flow channel is increased.

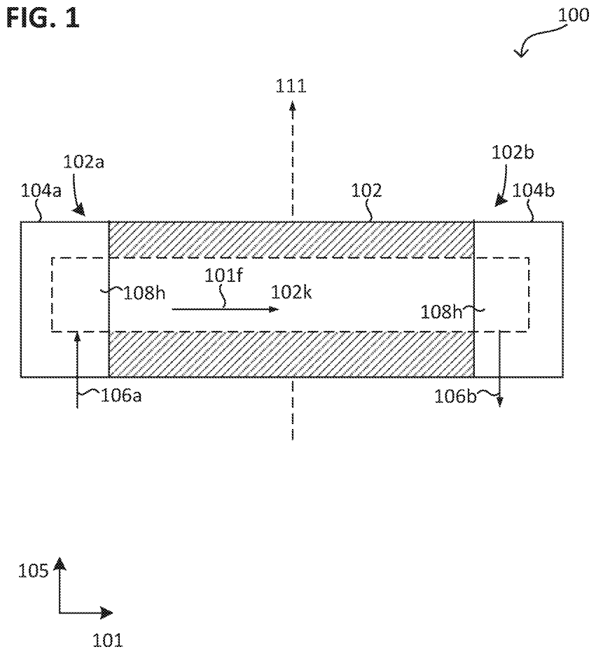

FIG. 1 illustrates a temperature control body housing 100 according to various embodiments in a schematic side view or cross-sectional view. The temperature control body housing comprises: a monolithic housing middle portion 102, a first housing end cap 104a, and a second housing end cap 104b, which are, for example, adjacent or at least directly opposite each other.

The housing middle portion 102 may be monolithically configured (i.e., be a single piece), e.g., be free of joining seams (such as welds and/or glue seams).

For example, the housing middle portion 102 may comprise or be formed from a metal. For example, the metal may comprise or be formed from (e.g., an alloy or compound of) one or more of the following metals: Aluminum, gold, silver, magnesium, and/or copper.

The housing middle portion 102 may be configured to be thermally conductive, for example formed of a material that is thermally conductive. As used herein, thermally conductive may be understood as having a thermal conductivity of about 100 watts per meter per Kelvin (W/m·K) or more, for example about 200 W/m·K or more (also referred to as high thermal conductivity), for example about 300 W/m·K or more, for example about 400 W/m·K or more. The greater the thermal conductivity, the more efficiently the temperature control body housing 100 can operate.

The housing middle portion 102 is penetrated by one or more than one fluid canal 102k. In other words, the or each fluid canal 102k extends through the housing middle portion 102 from a first side 102a (e.g., front side) of the housing middle portion 102 to a second side 102b (e.g., front side) of the housing middle portion 102 (along direction 101). For example, the or each fluid canal 102k may have an input (also referred to as a canal input) at the first side 102a of the housing middle portion 102 and an output (also referred to as a canal output) at the second side 102b of the housing middle portion 102.

For example, the housing middle portion 102 may be substantially cuboidal in shape.

The housing middle portion 102 is disposed between the first housing end cap 104a and the second housing end cap 104b. The first housing end cap 104a may be disposed on and/or connected to the first side 102a (e.g., face side) of the housing middle portion 102. The second housing end cap 104b may be disposed on and/or connected to the second side 102b (e.g., face side) of the housing middle portion 102.

The first housing end cap 104a includes a first fluid port 106a. The second housing end cap 104b includes a second fluid port 106b. The first fluid port 106a and the second fluid port 106b are fluidly connected to each other by means of the one or more than one fluid canal 102k.

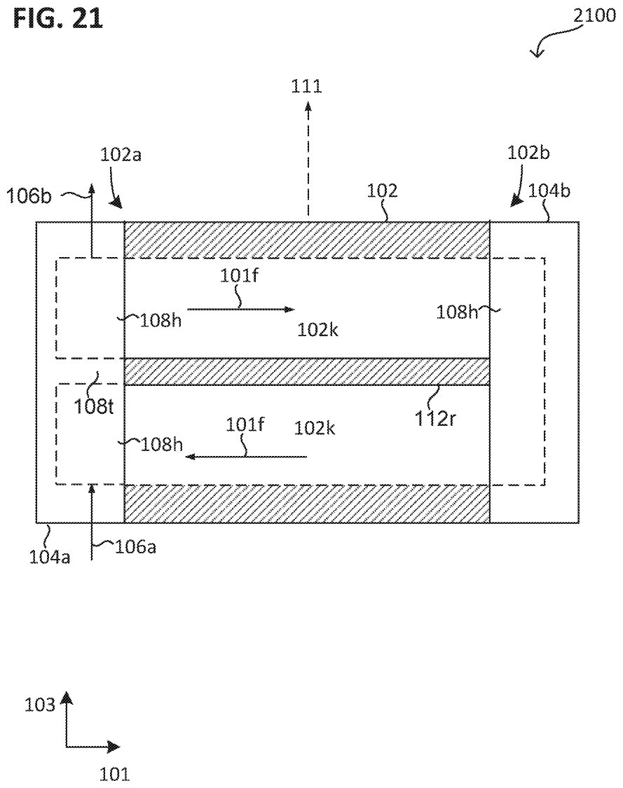

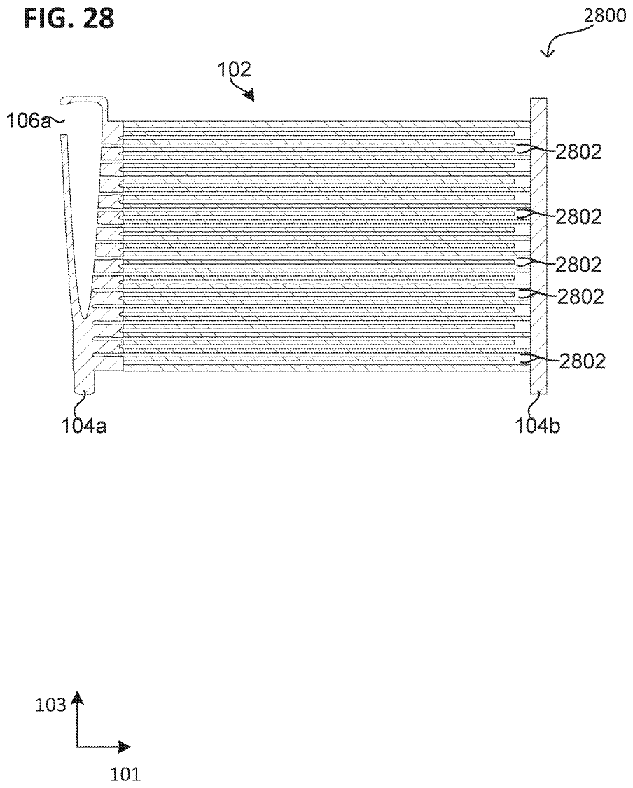

For example, the respective fluid port 106a, 106b may be adjacent to the one or more fluid canals 102k. For example, the respective fluid port of a housing end cap may be disposed on the top, bottom, or face thereof. In embodiments with an internal redirection of the flow path within the temperature control body (e.g., using a pair of fluid channels that provide a serpentine flow path in pairs), a housing end cap 104a may have both fluid ports (see, for example, FIG. 21 and FIG. 28).

For example, the respective housing end cap 104a, 104b may include a cavity 108h fluidly connecting the fluid port 106a, 106b of the housing end cap 104a, 104b to the one or more than one fluid canal 102k. The latter improves fluid distribution.

The or each fluid port 106a, 106b may protrude, for example, so that a hose may be attached, for example. The hose may be attached and/or secured to the respective fluid port 106a, 106b, for example, by means of a clamp, a coupling nut, or a kick connection.

The or each fluid port 106a, 106b may, for example, include or be formed from a protruding tube stub. The or each fluid port may, for example, comprise or be formed from a seal, such as an annular seal. The or each fluid port may, for example, comprise a threaded port. The or each fluid port may have, for example, a click-lock (i.e., a self-engaging closure).

In operation, a temperature control fluid (e.g., cooling fluid) can be supplied to the temperature control body housing 100 by means of the first fluid port 106a. The temperature control fluid flows through the housing middle portion 102 and can be withdrawn from the temperature control body housing by means of the second fluid port 106b. To do so, the temperature control fluid flows from the first housing end cap 104a through the one or more fluid canals 102k and into the second housing end cap 104b.

Accordingly, the temperature control body housing 100 may provide a fluid conduction path from the first fluid port 106a to the second fluid port 106b. For example, the fluid conduction path may include a plurality of branches extending side-by-side and connected in parallel (e.g., fanned out). For example, the fluid conduction path may be serpentine.

For example, the temperature control fluid may comprise or be formed from a temperature control gas and/or a temperature control liquid. For example, the temperature controlling fluid may comprise or be formed from water. Alternatively or additionally, the temperature control fluid may comprise or be formed from an oil, for example a synthetic and/or mineral oil. Alternatively or additionally, the temperature control fluid may comprise or be formed from the melt of a salt. In general, it may be understood that any suitable fluid medium (also referred to as fluid) may be used as the temperature control fluid.

In operation of the temperature control body housing 100, a flow direction 101f of the temperature control fluid may be from the channel inlet to the channel outlet. Direction 103 and/or direction 105 may be transverse to the flow direction 101f. Direction 101 may be in or opposite to the flow direction 101f.

If the housing middle portion 102 has more than one fluid canal 102k, the number of fluid canals 102k of the housing middle portion 102 may be at least 2 (i.e., 2 or more), e.g., at least 3, e.g., at least 5, e.g., at least 10, e.g., at least 15, e.g., at least 20. The greater the number of fluid canals 102k of the housing middle portion 102, the greater the temperature control performance may be. Alternatively or additionally, flow homogenization (uniformity) can be achieved by means of the design of the housing end caps. Exemplary flow homogenization measures have: the insertion of one or more baffle plates and/or the insertion of one or more fluid baffle plates into the housing end cap(s).

Reference is made herein to, among other things, characteristics of one fluid canal 102k of the housing middle portion 102 for ease of understanding. It may be understood that what is described for the one fluid canal 102k may optionally apply to any of a plurality of fluid canals 102k of the housing middle portion 102, for example, each fluid canal 102k of the housing middle portion 102.

Fluid canals 102k of the housing middle portion 102 that are immediately adjacent to each other may be separated from each other (also referred to as fluid-separated), for example, by means of a partition, as will be described in more detail later.

Optionally, the housing middle portion 102 and the housing end caps 104a may differ from each other in their chemical composition and/or thermal conductivity. Alternatively or additionally, the housing middle portion 102 and the housing end caps 104a may differ from each other in how they are manufactured. This simplifies manufacturing and will be explained in more detail below.

For example, the first housing end cap 104a and/or the second housing end cap 104b may include a plastic or be formed from the plastic. For example, the plastic may be a thermoplastic plastic or part of a composite material. This makes it easier to manufacture the respective housing end cap 104a, 104b using a molding process, which in turn is particularly cost-effective. Alternatively, of course, another plastic or composite material may be used, for example, to increase durability and/or to match the coefficient of thermal expansion to the housing middle portion 102.

Optionally, the housing middle portion 102 may include an extrusion product or may be formed from an extrusion product. The extrusion product may be formed from a compact (e.g., metal).

Extrusion is a continuous forming process for producing a strand of predefined shape from the compact. The compact may, for example, comprise or be formed from a metal, such as a ferrous alloy or a non-ferrous alloy. In extrusion, the heated but still solid compact (e.g. the metal) is pressed through a die and deformed by means of this die, the result of which emerges as a so-called strand. In the process, the compact is enclosed by a recipient—a very thick-walled tube. Thereafter, the strand is divided into a plurality of segments (also referred to as strand segments). The housing middle portion 102 may be formed based on an extrusion segment (also referred to as an extrusion product), e.g., with or without post-processing.

Extrusion is not to be confused with continuous casting. Continuous casting is one of the casting processes, while extrusion is one of the forming processes. The continuous manufacturing process, e.g., extrusion, achieves a particularly cost-effective manufacturing of the housing middle portion 102 with sufficiently high precision.

As a result of the continuous manufacturing process, the extrusion product (e.g., the entire housing middle portion 102) may be mirror symmetric, for example with respect to a plane 111 (then also referred to as a mirror plane). Alternatively or additionally, the extrusion product (e.g., the entire housing middle portion 102) may be at least sectionally translation symmetric, e.g., along direction 101, which is, for example, transverse to plane 111.

For example, the plane 111 may be transverse to the direction 101 and spanned by the directions 103, 105.

For example, the housing middle portion 102 may be cylindrical (in the sense of a general cylinder, such as having a polygonal base). The cylinder is formed when the contour of the first side 102a of the housing middle portion 102 is displaced along direction 101 by the length of the housing middle portion 102, where it then forms the second side 102b. In other words, the first side 102a and the second side 102b may substantially match in contour.

Optionally, the housing middle portion 102 may have substantially the same coefficient of thermal expansion (also simplified herein as coefficient of expansion) as the first housing end cap 104a and/or as the second housing end cap 104b. In other words, their coefficients of expansion may differ less than about 25% relative to each other. As used herein, relative deviation may be understood to mean, for example, the ratio of the deviation to the arithmetic mean. In formulas, the housing middle portion 102 may have a first coefficient of expansion A1 and the first housing end cap 104a or the second housing end cap 104b may have a second coefficient of expansion A2. The ratio of the deviation |A1−A2| to the arithmetic mean (A1+A2)/2 is then |A1−A2|/(A1/2+A2/2)=a, where the relative deviation a is 0.25 (i.e., 25%). However, the relative deviation a can also be smaller than about 25%, e.g., about 10% or less, e.g., about 5% or less, e.g., about 1% or less.

This permits the temperature control body housing 100 to be structurally particularly invariant to temperature variations. For example, this inhibits leaks from occurring, for example, increasingly so with smaller relative deviation.

That the coefficients of expansion differ less than 25% relative to each other can be achieved by selecting the materials of the housing middle portion and/or housing end cap(s) such that the difference in coefficient of expansion is minimized.

This can be achieved, for example, by using copper as a thermally highly thermally conductive and glass fiber-filled plastic. An example is a special polyamide-imide (PAI) with a glass fiber content of 30%. The relative deviation in the coefficients of thermal expansion between this special plastic and pure copper according to the calculation method described above is approximately 3%.

Optionally, the channel inlet and the channel outlet of the fluid canal 102k may differ in cross-sectional area by less than about 25% relative to each other, e.g., about 10% or less, e.g., about 5% or less, e.g., about 1% or less.

Adverse effects due to a difference in the coefficient of thermal expansion cannot be compensated only by means of a one-dimensional adjustment of the cross-sectional area, since the effect of the difference in the coefficient of thermal expansion is three-dimensional in nature.

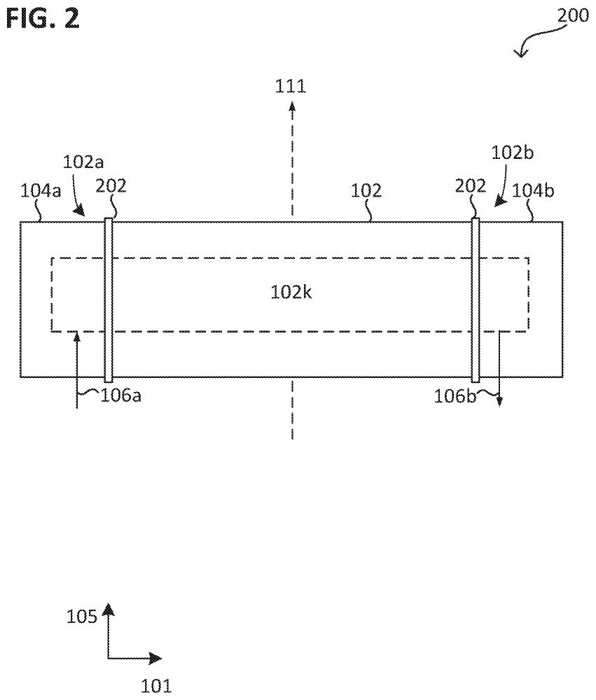

FIG. 2 ∫ a temperature control body housing 100 according to various embodiments 200 in a schematic side view or cross-sectional view. The temperature control body housing further comprises a first seal 202 by means of which the housing middle portion 102 is fluid-tightly connected to the first housing end cap 104a. Alternatively or additionally, the temperature control body housing 100 comprises a second seal 202 by means of which the housing middle portion 102 is connected to the second housing end cap 104b fluid-tight.

The gasket facilitates sealing the interior of the temperature control body housing 100 from the outside world. For example, the seal makes it possible to compensate for manufacturing tolerances.

Optionally, the housing middle portion 102 may include a circumferential first groove for receiving the first seal 202. Alternatively or additionally, the housing middle portion 102 may include a circumferential second groove for receiving the second seal 202. Once the temperature control body housing 100 is assembled, the seals 202 may each be received in the corresponding groove of the housing middle portion 102.

Optionally, the first housing end cap 104a may include a circumferential first groove for receiving the first seal 202. Alternatively or additionally, the second housing end cap 104b may include a circumferential second groove for receiving the second seal 202. Once the temperature control body housing 100 is assembled, the seals 202 may each be received in the corresponding groove of the housing end cap 104a, 104b.

The or each seal 202 may, for example, comprise or be formed from a ring seal. The or each seal 202 may, for example, comprise or be formed from an elastomer.

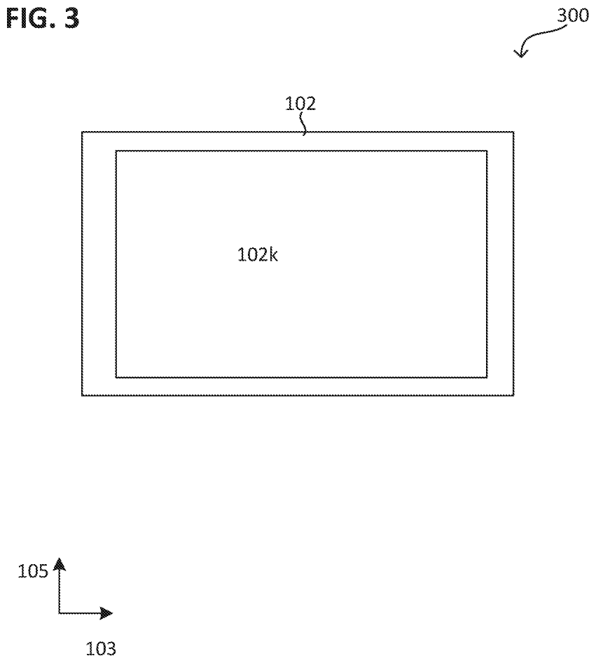

FIG. 3 illustrates a temperature control body housing 100 according to various embodiments 300 in a schematic side view (e.g., on its face) or cross-sectional view (e.g., cut along plane 111). The housing middle portion 102 may be a housing frame (e.g., in the form of a frame) of the temperature control body housing 100. The frame may be understood as the side enclosing portion of the temperature control body housing 100.

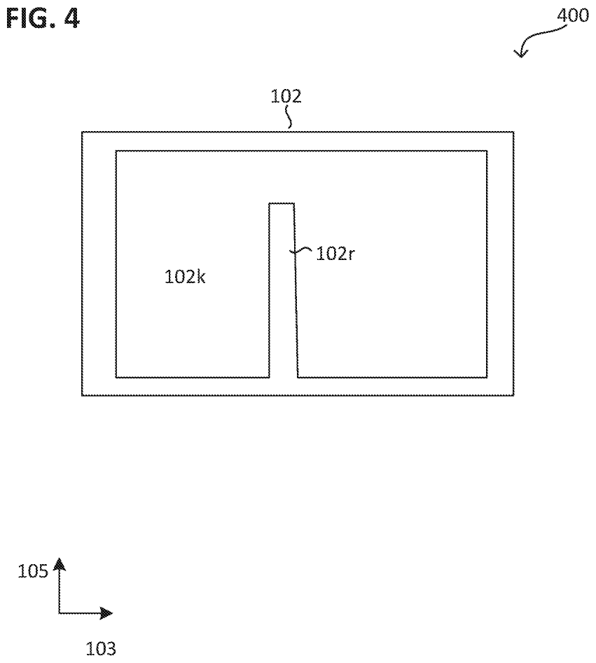

FIG. 4 illustrates a temperature control body housing 100 according to various embodiments 400 in a schematic side view (e.g., on its face) or cross-sectional view (e.g., cut along plane 111). The housing middle portion 102 may include one or more than one first temperature control fin 102r (also referred to as a first type temperature control fin) extending into the fluid canal 102k. For example, the first type temperature control fin (e.g., cooling fin) may have a free end, i.e., may project freely. In other words, the fluid canal 102k may have two side-by-side channel sections with a first temperature control fin 102r (e.g., cooling fin 102r) disposed between them. The temperature control fin increases the heat transferring surface area, thereby promoting heat transfer.

The higher (extent along direction 105) the first temperature control fin 102r is, the more fluid-separated the channel sections can be from each other. If the two channel sections are fluid-separated from each other to such an extent that they can hardly (i.e., essentially none) exchange the temperature control fluid with each other, the two channel sections can be functionally considered as independent fluid channels. This is the case, for example, when the channel inlet and/or the channel outlet are essentially the only openings of the fluid channel.

The more first temperature control fins 102r the housing middle portion 102 has per fluid canal 102k, the greater the temperature control performance can be. For example, the number of first temperature control fins 102r per fluid canal 102k may be at least 2 (i.e., 2 or more), e.g., at least 3, e.g., at least 5, e.g., at least 10, e.g., at least 15, e.g., at least 20.

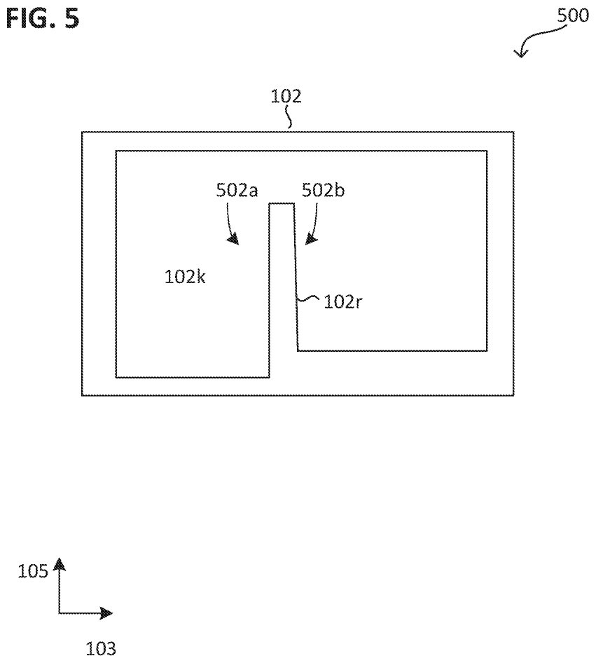

FIG. 5 illustrates a temperature control body housing 100 according to various embodiments 500 in a schematic side view (e.g., on its face) or cross-sectional view (e.g., cut along plane 111). The or each first temperature control fin 102r may have an asymmetric contour (e.g., in section along plane 111). Illustratively, the first temperature controlling fin 102r may be beveled, for example, or may have different lengths on the left and right sides, for example.

For example, the channel sections of the fluid canal 102k between which the first temperature control fin 102r is disposed, as shown, may differ from each other in height (extent along direction 105). This achieves that the first temperature control fin 102r has opposing side surfaces 502a, 502b that are adjacent to the fluid canal and differ from each other, e.g., in their surface area and/or extent (e.g., along the direction of extension of the temperature control fin).

This asymmetry (for example, of the side surfaces 502a, 502b) achieves that the temperature control power can be spatially adjusted. For example, the temperature control power can be adapted to counteract a gradient (i.e. a continuous slope) in the temperature of the temperature control fluid.

The gradient in the temperature of the temperature control fluid may be caused, for example, by the temperature control fluid gradually heating as it flows through the temperature control body housing 100. This can cause a gradient in the temperature difference between the temperature control fluid and the temperature control body housing 100, or a gradient in the heat absorption rate of the temperature control fluid.

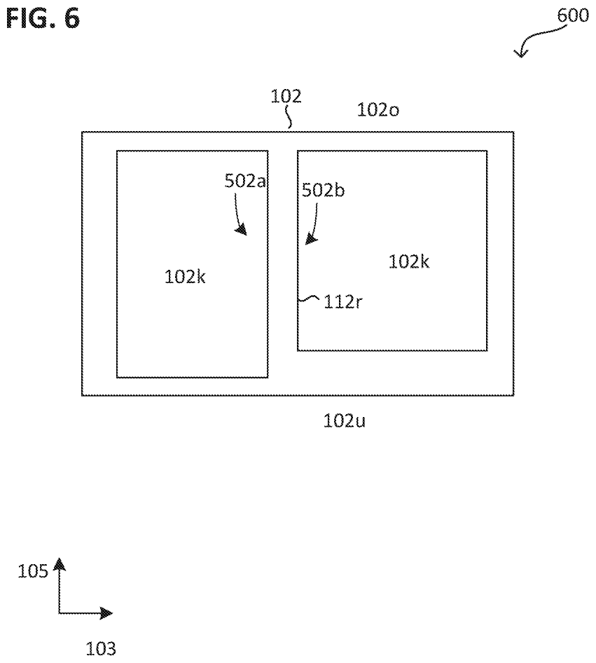

FIG. 6 illustrates a temperature control body housing 100 according to various embodiments 600 in a schematic side view (e.g., on its front face) or cross-sectional view (e.g., cut along plane 111). The housing middle portion 102 may include two fluid channels 102k immediately adjacent to each other, and may further include a second temperature control fin 112r (also referred to as a second type temperature control fin or a fluid-separating temperature control fin) that separates the two fluid channels 102k from each other. In other words, the second temperature control fin 112r (e.g., cooling fin 112r) may be formed as a partition that fluid-separates the two fluid channels 102k from each other.

The second type temperature control fin 112r, formed as a partition, may extend from an upper side 102o of the housing middle portion 102 to a lower side 102u of the housing middle portion 102. In other words, the second type temperature control fin 112r may connect two opposite sides 102o, 102u of the housing middle portion 102. For example, the two fluid channels 102k may have no fluid connection to each other disposed between their channel inlet and their channel outlet.

Optionally, the housing middle portion 102 may include more than two fluid channels 102k (not shown), immediately adjacent fluid channels 102k of which are separated from one another by one of the second temperature control fins 112r. Optionally, the housing middle portion 102 may have more than one first temperature control fin 102r (not shown) extending into the fluid canal 102k per fluid canal 102k.

Optionally, the or each second temperature control fin 112r may have an asymmetric contour (e.g., in section according to plane 111). What has been described above for the first temperature control fin 102r with regard to the asymmetry can, for example, apply by analogy to the second temperature control fin 112r.

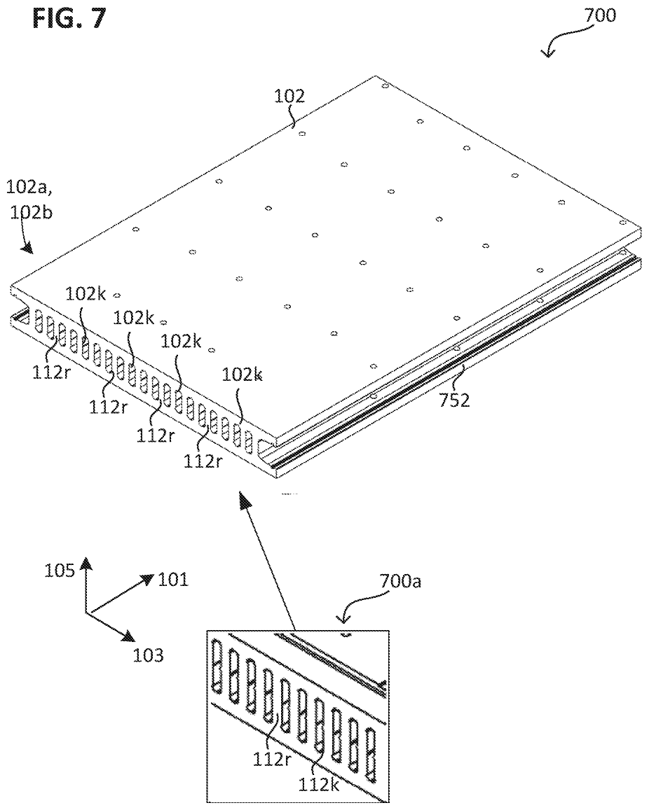

FIG. 7 illustrates a temperature control body housing 100 according to various embodiments 700 in a schematic perspective view and detailed view 700a, e.g., on the first side 102a or second side 102b of the housing middle portion 102.

According to various embodiments, the housing middle portion 102 may comprise a one-piece or two-piece extruded section. The flow is from the front to the rear.

As shown, the housing middle portion 102 may have a plurality of temperature control channels 102k (e.g., cooling channels 102k) arranged in a row adjacent to each other. As shown, the housing middle portion 102 may include at least 10 or more temperature control channels 102k, e.g., may include 20 or more temperature control channels 102k.

Optionally, the housing middle portion 102 may include a mounting structure 752 on the side thereof. By means of the mounting structure 752, the housing middle portion 102 and thus the temperature control body housing 100 can be attached to electronics to be temperature controlled (e.g., cooled).

For example, the housing middle portion 102 may include one or more than one laterally protruding lip as a mounting structure 752. For example, the lip may include one or more than one through-openings. For example, the lip may be profiled.

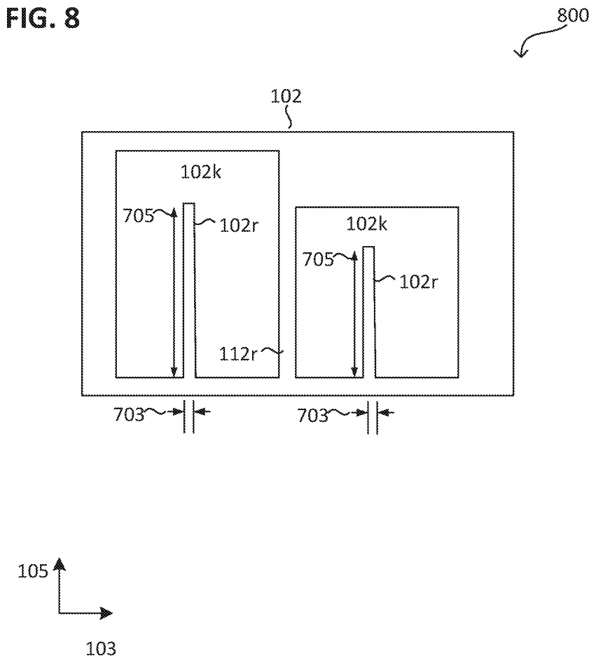

FIG. 8 illustrates a temperature control body housing 100 according to various embodiments 800 in a schematic side view (e.g., on its face) or cross-sectional view (e.g., cut along plane 111).

For example, the housing middle portion 102 may have a plurality of temperature control fins (e.g., first type and/or second type) that differ from one another in their extension 705 along direction 105 (also referred to as height). Alternatively or additionally, the housing middle portion 102 may have a plurality of temperature control fins (e.g., first type and/or second type) that differ from one another in their extent 703 (also referred to as thickness) along direction 103. Direction 103 and/or direction 105 may be transverse to flow direction 101f.

For example, the housing middle portion 102 may have a plurality of temperature control channels 102k that differ from one another in their extension 705 (also referred to as height) along direction 105. Alternatively or additionally, the housing middle portion 102 may have a plurality of temperature control channels 102k that differ from one another in their extent 703 (also referred to as thickness) along direction 103.

For example, the housing middle portion 102 may include a plurality of temperature control channels 102k having facing sides, the facing sides differing in cross-sectional area from one another.

For example, the housing middle portion 102 may include a plurality of temperature control channels 102k that differ in cross-sectional area with respect to plane 111.

The parameters of the expansion or cross-sectional area can be used to adjust the spatial distribution of the temperature control power. For example, the differences in expansion or cross-sectional area can cause a difference in local temperature control performance. For example, the difference in local temperature control power may be configured to counteract a gradient in the temperature of the temperature control fluid.

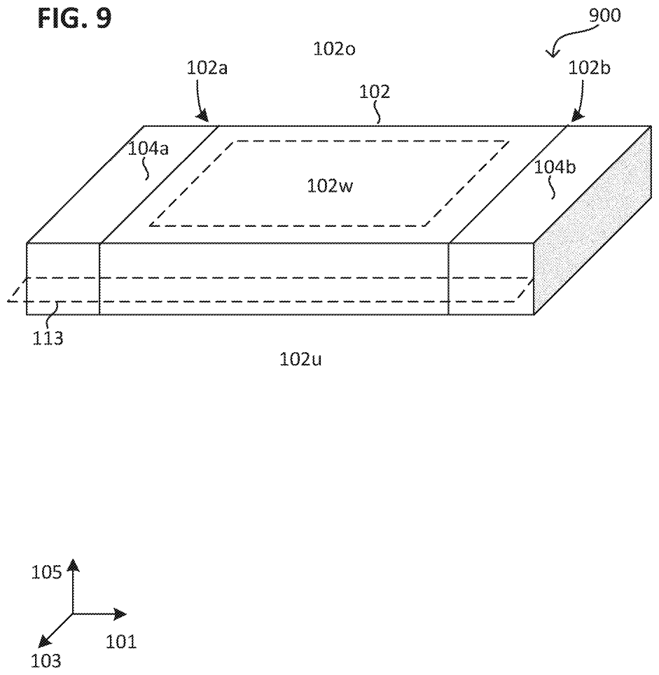

FIG. 9 illustrates a temperature control body housing 100 according to various embodiments 900 in a schematic perspective view. The housing middle portion 102 may include one or more heat output receiving surfaces 102w. For example, the or each heat output receiving surface 102w may be disposed between the first housing end cap 104a and the second housing end cap 104b.

For example, the heat output receiving surface 102w may be flat (i.e., planar) and optionally polished and/or planarized.

Reference is made herein to, among other things, a heat output receiving surface 102w. However, the temperature control body housing 100 may have more than one heat output receiving surface 102w, e.g., multiple spatially separated heat output receiving surfaces 102w. By analogy, what is described for the heat output receiving surface 102w may apply to multiple heat output receiving surfaces 102w.

Optionally, the housing middle portion 102 may include at least two heat output receiving surfaces 102w between which the one or more than one temperature control channels 102k are disposed. For example, the housing middle portion 102 may include one or more than one first heat output receiving surface 102w on a third side 103o (illustratively, top side 102o). Alternatively or additionally, the housing middle portion 102 may have one or more than one second heat output receiving surface (hidden in this view) on a fourth side 102u (illustratively bottom side 102u). This expands the possible uses of the temperature control body housing 100, as the electronics to be temperature controlled (e.g., cooled) may be mounted on the bottom side 102u and/or the top side 102o, as desired.

Optionally, the temperature control body housing 100 may be arranged in mirror symmetry with respect to a plane 113 (spanned by directions 101 and 103) so that a heat output receiving surface 102w is provided on both sides.

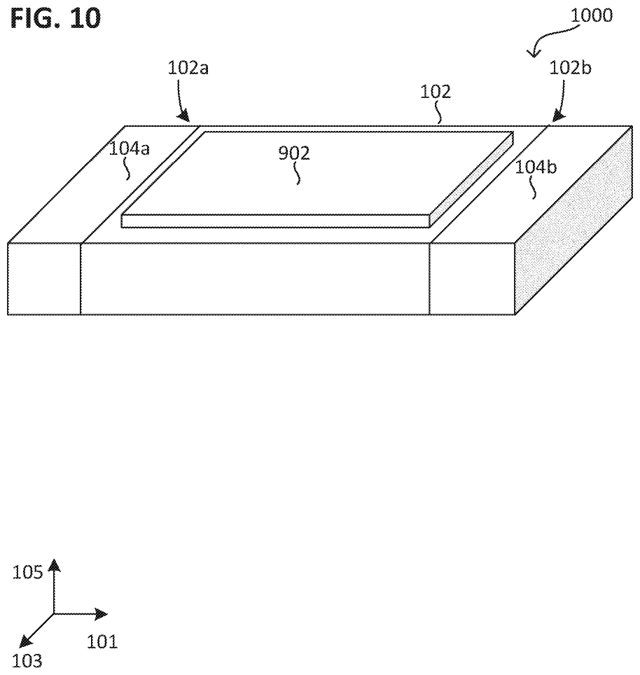

FIG. 10 illustrates a temperature control body housing 100 according to various embodiments 1000 in a schematic perspective view. The temperature control body housing may include a heat conductive material 902 (e.g., a layer of the heat conductive material) disposed on, e.g., in physical contact with, the heat output receiving surface 102w.

In general, various materials may be used as the thermal conductive material. For example, the heat conductive material may be provided as a so-called heat conductive mat (also referred to as a heat conductive pad), which is prefabricated and placed on the heat output receiving surface 102w. Alternatively or additionally, the heat conductive material may be provided as a so-called heat conductive paste (i.e., the heat conductive material may be a viscous paste) with which the heat output receiving surface 102w is coated. However, the thermal conductive material may be more viscous than a thermal conductive paste. Optionally, the thermal conductive material may also comprise or be formed from an adhesive.

The heat-conducting mat can, for example, comprise plastic (e.g. a plastic film) or be formed from it. Alternatively or additionally, the heat conducting mat may have particles embedded in, for example, the plastic. The plastic of the heat conductive mat may be, for example, thermoplastic plastic (also referred to as a thermoplastic). Alternatively or additionally, the plastic of the heat-conducting mat may be elastic, for example if it comprises or is formed from a rubber and/or silicone.

For example, the thermal paste may comprise or be formed from a heterogeneous mixture. The heterogeneous mixture may comprise a solid (e.g., a plurality of particles) and a viscous (i.e., liquid, flowable, or spreadable) material. For example, the viscous material may comprise or be formed from an oil, e.g., silicone oil. For example, the solid material (e.g., the solid particles) may comprise or be formed from zinc oxide, aluminum, copper, graphite, and/or silver.

However, the heat-conducting material may also be a homogeneous mixture or a liquid (at room temperature or higher) metal alloy or formed therefrom.

The thermal conductivity and/or expansion of the thermal conductive material 902 (also referred to as thickness in the direction 105) may affect the thermal resistance provided by the thermal conductive material 902.

For example, the thermal conductivity of the thermal conductive material 902 may be greater than about 1 watt per meter and kelvin (W/m·K), for example, greater than about 5 W/m·K, for example, greater than about 7.5 W/m·K, for example, in a range from about 1 W/m·K to about 10 W/m·K. Alternatively or additionally, the thermal conductivity of the thermal conductive material 902 may be less than the thermal conductivity of the housing middle portion 102.

Alternatively or additionally, the thickness of the thermal conductive material 902 (in the direction 105) may be less than about 5 mm (millimeters), for example, less than about 2.5 mm, for example, less than about 1 mm.

Optionally, the thermal resistance of the heat conducting material can have a slope. In addition to the thermal conductivity, the surface area and thickness of the thermal conductive material are also included in the thermal resistance.

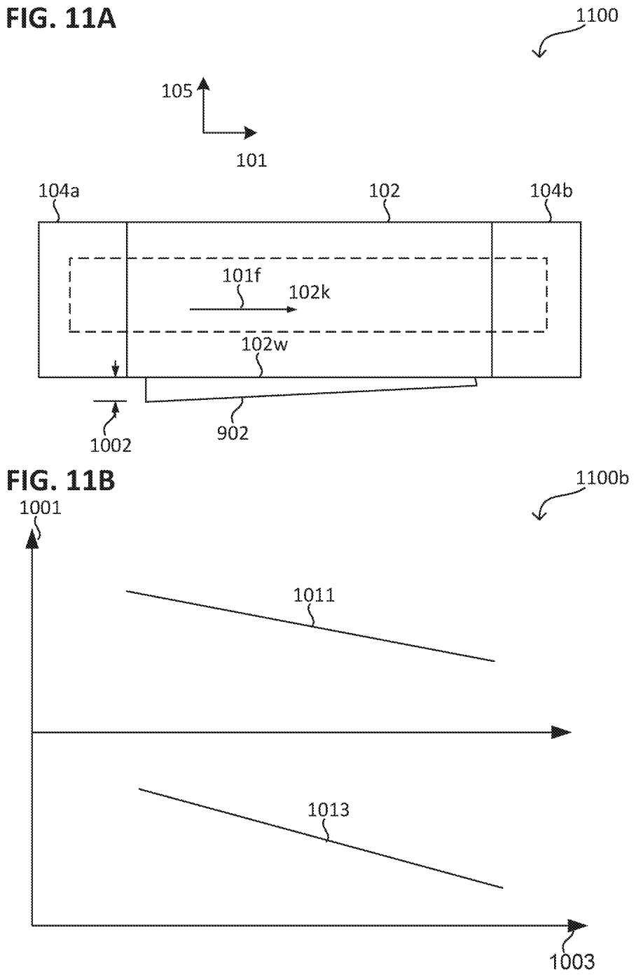

FIG. 11A illustrates a temperature control body housing 100 according to various embodiments 1100 in a schematic side view or cross-sectional view, and FIG. 11B illustrates a schematic diagram 1100b in which a thermal power quantity 1001 is plotted over the spatial extent 1003 in the flow direction 101f of the temperature control fluid. Here, the heat output quantity 1001 is the heat output absorption 1011 of the heat output receiving surface 102w and a thermal resistance 1013 of the heat conductive material 902.

The thermal power quantity of a body can refer to the state of the body when it is in thermal equilibrium, i.e. it absorbs as much thermal power as it releases.

The heat output absorption 1011 of the body may be understood as a measure of the heat output absorbed by the body, for example, representing the heat output absorbed per area (transverse to heat transport, i.e., conduction) during operation (e.g., in watts per square meter). The heat output absorption 1011 may vary spatially and/or depend on the actual state of operation. For example, the heat output absorption 1011 may be a function of a spatially varying thermal conductivity of the body. For example, the heat output absorption 1011 may be a function of a spatially varying temperature of the body. For example, the heat output absorption 1011 may be a function of a spatially varying temperature of the fluid flowing through the body.

The thermal resistance 1013 of the body can be understood as a measure of the temperature difference that arises in a body when a heat flow (heat per unit time or thermal power) passes through, and which is required, for example, as a thermal driving force. The thermal resistance 1013 may vary spatially. For example, the thermal resistance 1013 may be a function of a spatially varying thermal conductivity of the body, a spatially varying cross-sectional area (across the heat transport) of the body, or a spatially varying extent 1002 of the body (along the heat transport). The thermal resistance is a quantity independent of operation, and may optionally be specified normalized to temperature difference. For example, thermal resistance (also referred to as thermal resistance) may be the extent 1002 of the body (along the heat transport) divided by the product of the thermal conductivity and the cross-sectional area through which conduction occurs. Conduction refers to heat transport by means of heat conduction, e.g. according to Fourier's law.

The heat output absorption 1011 of the heat output receiving surface 102w may have a first slope (also referred to as a heat absorption slope) during operation of the temperature control body housing 100. For example, the heat absorption gradient may be directed from the channel inlet of the fluid canal 102k (e.g., temperature control channel) to the channel outlet of the fluid canal 102k. In other words, the heat output absorption 1011 of the heat output receiving surface 102w may decrease along the flow direction 101f of the temperature control fluid.

The direction of the slope can be understood as the direction in which the thermal power quantity 1001 decreases.

The thermal resistance 1013 of the thermal conductive material 902 may have (for example, during operation of the temperature control body housing 100) a second slope (also referred to as a thermal resistance gradient). For example, the thermal resistance gradient may be directed from the channel inlet of the fluid canal 102k to the channel outlet of the fluid canal 102k. In other words, the thermal resistance may decrease along the flow direction 101f of the temperature control fluid.

This achieves that the thermal resistance gradient and the thermal power absorption gradient at least partially compensate each other. For example, a high temperature differential or heat output absorption 1011 is compensated by a high thermal resistance 1013 and vice versa.

The net heat flux absorbed by the heat output receiving surface 102w through the heat conducting material 902 then has a lower slope than the thermal resistance 1013 and/or the heat output absorption 1011. This homogenizes the temperature control performance of the temperature control body housing 100.

For example, the thermal conductive material 902 may have a gradient in the layer thickness 1002. This achieves a thermal resistance gradient opposite to the gradient in the layer thickness 1002.

For example, the thermal conductive material 902 may have a gradient in thermal conductivity. This achieves a thermal resistance gradient along the gradient in thermal conductivity.

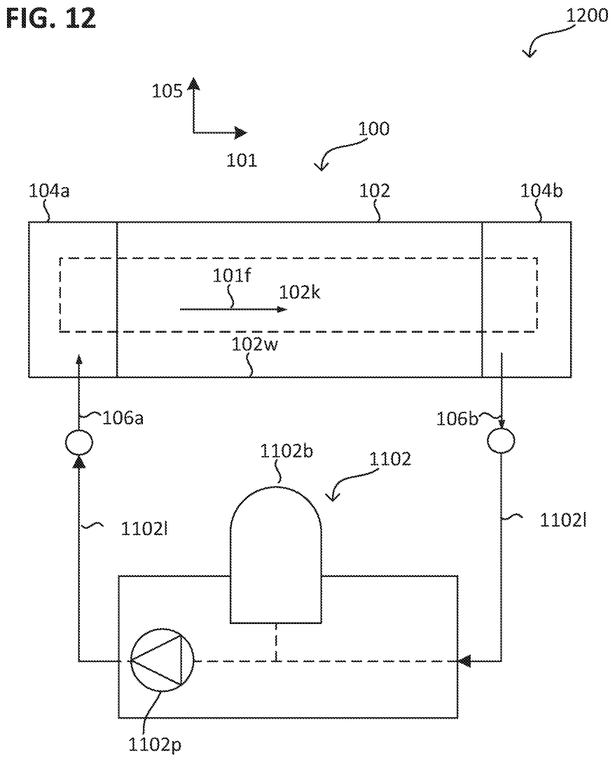

FIG. 12 illustrates a temperature control arrangement 1200 according to various embodiments in a schematic side view or cross-sectional view. The temperature control arrangement 1200 includes the temperature control body housing 100 and a fluid supply 1102. What is described herein by way of example for a processor as an exemplary electrical component may be understood to mean that what is described may apply by analogy to other electrical components.

The fluid supply 1102 may be coupled to the two fluid ports 106a, 106b of the temperature control body housing 100. Further, the fluid supply 1102 may be configured to provide fluid flow in the direction 101f (also referred to as flow direction 101f) through the temperature control body housing 100.

The fluid supply 1102 may be configured to supply the temperature control fluid to the first fluid port 106a and withdraw the temperature control fluid from the second fluid port 106b. The temperature control fluid then flows from the first housing end cap 104a, through the one or more fluid canals 102k, to the second housing end cap

In principle, it can be understood that fluid flow can also be provided along a serpentine path 101f. Then, the temperature control fluid may flow multiple times from the first housing end cap 104a, through the one or more than one fluid canal 102k to the second housing end cap 104b, and back again. Herein, for ease of understanding, reference is made to a flow direction 101f, which may apply, for example, by analogy to a section of serpentine path 101f (depending on the direction of flow). In a serpentine path 101f, fluid may be supplied and withdrawn on the same side 102a, for example, by an end cap having both a supplying fluid port 106a and a discharging fluid port 106b.

The fluid supply 1102 may, for example, comprise a fluid energy machine 1102p (e.g. a pump) which is configured to supply mechanical work to the temperature control fluid so that it is excited to flow. The fluid supply 1102 may comprise, for example, an equalization reservoir 1102b, which is configured to receive and store the temperature control fluid. The fluid supply 1102 may include, for example, one or more than one fluid conduit (e.g., a hose) fluidly connecting the fluid energy machine to the first fluid port 106a and the second fluid port 106b. The fluid supply 1102 may include, for example, one or more than one valve to control fluid flow.

For example, the fluid energy machine 1102p may include a control device configured to control and/or regulate the flow of the temperature control fluid based on a temperature.

The term “control device” can be understood as any type of logic implementing entity that may, for example, have circuitry and/or a processor that can, for example, execute software stored in a storage medium, in firmware, or in a combination thereof, and issue instructions based thereon. For example, the control device may be configured using code segments (e.g., software). For example, the control device may comprise or be formed from a programmable logic controller (PLC).

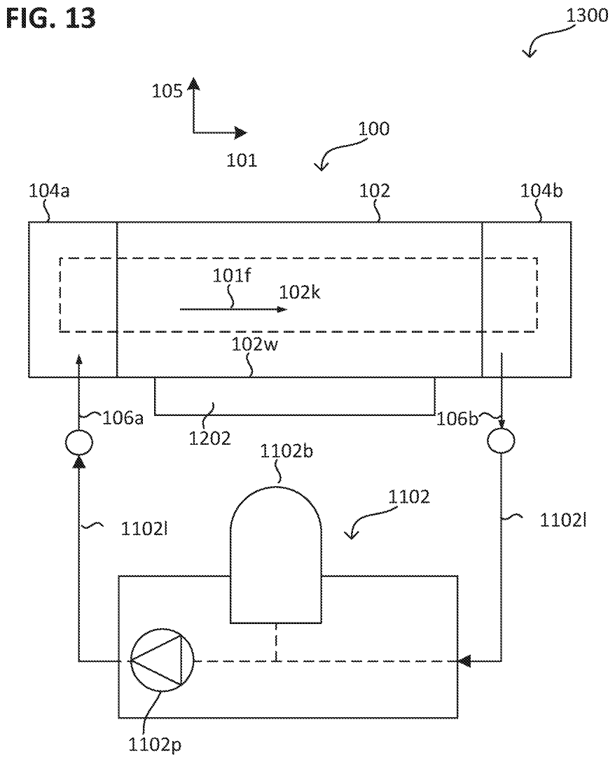

FIG. 13 illustrates an electrical device 1300 according to various embodiments in a schematic side view or cross-sectional view. The electrical device includes the temperature control body housing 100 and one or more than one electrical component 1202, such as one or more than one processor 1202. For example, the electrical device 1300 may be part of a computing device, such as a server or the like.

What is described herein by way of example for specific electrical components can be understood to mean that this can also apply by analogy to other electrical components 1202. In principle, however, other electrical components 1202 can also be cooled by means of the temperature control body housing 100 (i.e., thermal energy is extracted from them).

The term “processor” may be understood as any type of entity that allows processing of data or signals. For example, the data or signals may be handled according to at least one (i.e., one or more than one) specific function performed by the processor. A processor may include or be formed from an analog circuit, a digital circuit, a mixed signal circuit, a logic circuit, a microprocessor, a central processing unit (CPU), a graphics processing unit 1529 (GPU), a digital signal processor (DSP), a programmable gate array (FPGA), an integrated circuit, active or passive components that may be cooled (e.g., MOSFETs, RAM, etc.), or any combination thereof.

The electrical device 1300 may optionally include fluid supply 1102 coupled to the two fluid ports 106a, 106b of the temperature control body housing 100.

Further aspects according to various embodiments are described below, to which the aspects described above may apply by analogy, e.g., to the temperature control module described below.

The temperature control module described below may generally comprise: a plurality of (e.g., exposed and/or planar) temperature control elements (e.g., temperature control bodies); and a fluid conduit having a first fluid port (also referred to descriptively as a fluid inlet) and a second fluid port (also referred to descriptively as a fluid outlet); wherein the plurality of temperature control elements are spaced apart from (e.g., embedded in) one another by the fluid conduit (e.g., separated from and/or fluidly coupled to one another in pairs by a portion of the fluid conduit); wherein the plurality of temperature control elements have greater thermal conductivity than the plurality of temperature control elements (e.g., the plurality of temperature control bodies).(e.g., embedded therein) at a distance from one another by the fluid conduit (e.g., so as to be separated from one another in pairs by a portion of the fluid conduit and/or fluidly coupled to one another); wherein the plurality of temperature control elements have a greater thermal conductivity than the fluid conduit and/or wherein the plurality of temperature control elements differ from one another in their thermal conductivity. For example, the fluid conduit can provide a flow path from the first fluid port to the second fluid port that passes by and/or through each of the plurality of temperature control elements. For example, the fluid conduit may be a load-bearing structure (i.e., the material thereof may be rigid, a thermoset, and/or a thermoplastic). For example, the fluid conduit may include one or more than one mounting structure (e.g., through-holes). For example, the fluid conduit may be monolithic or may comprise or be formed from two half-shells joined together, for example at least one of the two half-shells being monolithic and/or supporting the plurality of temperature control elements. For example, the fluid conduit and/or may comprise or be formed from at least one of the plurality of temperature control elements comprising a plastic. For example, at least one of the plurality of temperature control elements may comprise or be formed from a metal (e.g., high thermal conductivity metal) (e.g., copper). The temperature control element of the temperature control module may, but need not necessarily, include a temperature control body housing.

For example, each of the plurality of temperature control elements may include a (e.g., exposed and/or planar) heat output receiving surface (also referred to as a functional surface) that protrudes from the fluid conduit, for example.

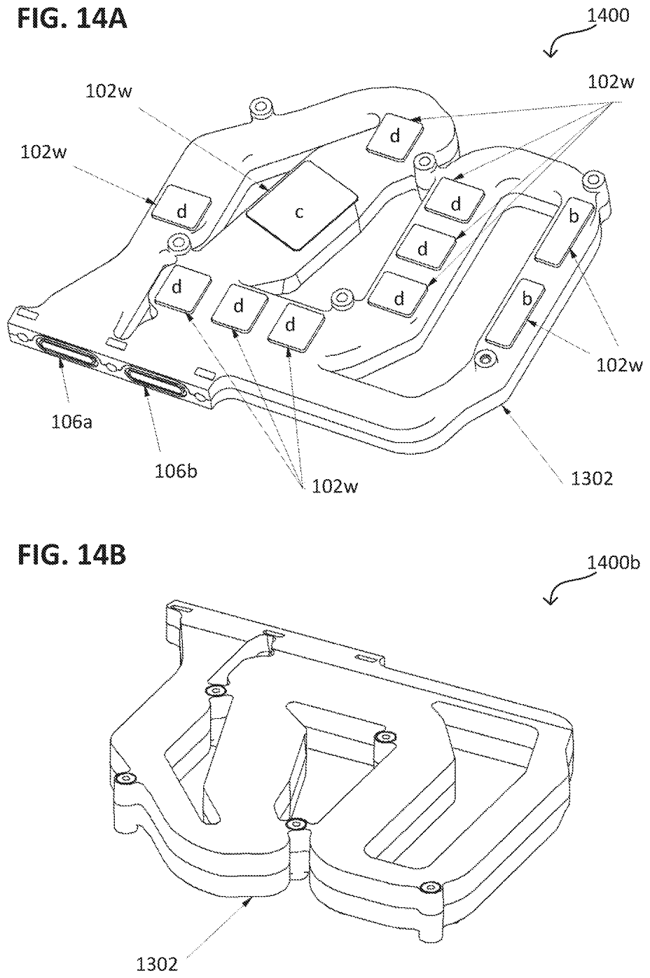

FIG. 14A illustrates a temperature control module 1400 according to various embodiments in a schematic perspective view from below, and FIG. 14B illustrates the temperature control module 1400 in a schematic perspective view 1400b from above.

The temperature control module 1400 may include a plurality of exposed heat output receiving surfaces 102w, e.g., each provided by means of a heat receiving plate or temperature control body housing 100. Further, the temperature control module 1400 includes a fluid conduit 1302 that provides a fluid flow path past the plurality of heat output receiving surfaces 102w (e.g., in series).

A large number of electrical components (hereinafter referred to as components) may require specific active temperature control (e.g. cooling and/or heating) for their (optimum) functionality according to individual component properties. Decisive component properties are operating temperature (minimum/maximum/optimum) and electrical/thermal power. The temperature control can take into account both internal thermal loads of the components (e.g. energy conversion within electronic components) and externally imposed thermal influences on the components (e.g. radiative and/or convective heat transfer between component and environment). Technical component groups and systems usually consist of a large number of components as individual components.

In many cases, the operating temperature of components has a global impact on decisive parameters such as operating capability, energy efficiency, service life and performance of the entire system. Targeted active temperature control of specific components or component group areas by a fluid-flow temperature control module 1400 is therefore helpful in many applications. The temperature control module 1400 can have one or more than one of the following features:
Realization of optimal operating temperatures for all actively temperature controlled components of the technical system, e.g. according to the individual component properties; and/or
maximum thermal efficiency of the temperature control module, i.e. minimum energy losses during heat transfer between components and fluid

According to various embodiments, the temperature control of technical component groups is performed by a large-5 area contacting of the component group areas or components to be actively temperature controlled by means of one or more thermal functional surfaces 102w of the temperature control module 1400. The thermal functional surfaces 102w of the temperature control module 1400 have a highly thermally conductive material (usually metals such as aluminum and copper) or are formed therefrom. As a result, heat transfer is realized between actively temperature controlled component group area or components and fluid. A thermal functional surface 102w thereby contacts one or more than one component or one or more than one component group area. The fluid is guided by means of a housing, the material of which may be the same as or different from that of the thermal function surface. The large-scale use of a homogeneous material for one or more than one thermal functional surface 102w (also referred to as heat output receiving surface in connection with heat absorption) of the temperature control module 1400 has the consequence that, under certain circumstances, not all individual thermal component properties are sufficiently taken into account. For example, components with a low power density are connected with the identical material as components with a much higher power density. As a result, the temperature control of individual component group areas and components, according to their component properties, is not necessarily appropriate.

In other words, optimal individual component temperatures are not necessarily realized. Furthermore, the large-area use of highly thermally conductive material on the functional surface 102w favors mutual thermal influence of spatially close components or component group areas (also referred to as “thermal smearing”). For example, unwanted heat transfer occurs from components of high power density and temperature compatibility to components of lower power density and temperature compatibility.

Both of the effects described above can promote temperature control of components or component group areas that is not in line with requirements. This leads to undesirable losses of the optimum operability, energy efficiency, service life and performance of the components and/or the component group. During operation of the temperature control module 1400, indirect heat transfer processes (conductive, convective, thermal radiation absorption or emission) occur in areas of the temperature control module 1400 that do not have direct thermal contact between actively temperature controlled components or component group areas and the thermal functional surface 102w. For example, heat transfer processes take place between temperature control module 1400 and ambient medium and/or surrounding solids (electronic components, printed circuit boards, housing components, etc.).

In the case of a temperature control module 1400 comprising a homogeneous material system, the described indirect heat transfer processes cannot be inhibited. For example, heat is transferred via the thermal function surface 102w even in areas of the temperature control module 1400 that do not exhibit contact the temperature-controlled components. The effects described impair the overall efficiency and function of the temperature control module.

Highly thermally conductive materials are also generally good electrical conductors. Therefore, the large-area use of highly electrically conductive materials takes place through the thermal functional area(s) 102w. Accordingly, highly electrically conductive materials are often located in close proximity to electrically non-insulated components of the component to be temperature controlled (e.g., cooled). This creates an increased risk potential for electrical short circuits, resulting in the need for elaborate assembly and quality control, or the implementation of measures to prevent electrical short circuits, for example by using insulating material.

The Temperature Control Module 1400 features a demand-oriented material selection in defined areas of the temperature control module according to the required technical functionality. This is achieved by using a composite material system. Different areas can have the following functionalities or combinations of these, for example:
high thermal conductivity or low thermal conductivity;
electrically conductive or electrically insulating;
mechanically loaded or mechanically unloaded.

Size, geometric shape and material of the thermal function surfaces 102w correspond to the individual requirements of the components to be temperature controlled (e.g. cooled) (according to dimensions and shape of the temperature controlled components or component areas). Areas of the temperature control module 1400 (e.g. the fluid line) which do not have a direct connection with components to be temperature controlled can be made of low thermal conductivity material.

For example, one or more than one thermal functional surface 102w may be bonded into the fluid conduit 1302, may be end-enclosed (“overmolded”) by a fluid conduit (e.g., made by injection molding) of plastic, or may be positively clamped with a seal, for example, made of an elastomer. Multiple thermal functional surfaces 102w of a temperature control module may be thermally isolated from each other by means of the low thermal conductivity fluid conduit 1302.

This achieves a low mutual thermal influence, i.e. inhibits “thermal smearing”. This achieves temperature control of individual components or component areas as required. This further improves energy efficiency and performance and increases the service life of the temperature-controlled individual components and the entire technical system. This also minimizes the risk of electrical short circuits. This also maximizes the thermal efficiency of the temperature control module 1400, for example by minimizing indirect heat transfer.

The temperature control module 1400 thus has a material selection according to requirements by means of a material composite system, and thus achieves different functionalities at defined points/positions of the temperature control module 1400 through which fluid flows.

The temperature control module 1400 can be used, for example, for temperature control (e.g. cooling) of a graphics card. The graphics card has several areas to be temperature controlled, corresponding to the components on its circuit board, which have different requirements with regard to their temperature controlling (e.g. cooling). These requirements are taken into account in the design.

Examples of components that need to be actively temperature controlled include: Graphics processing unit (GPU), which is a component with high thermal power density and high temperature tolerance; memory media (e.g. random-access memory—RAM), which are components with low thermal power density and low temperature tolerance; voltage regulation module (VRM), which is a component with medium thermal power density and high temperature tolerance.

Several (e.g., all) of the components to be actively temperature controlled may be thermally connected to (e.g., conductively coupled to) the temperature control module 1400 with high thermal conductivity copper structures 102w, according to the size of their heat transferring surface. The fluid conduit 1302 may be made of thermally low conductive plastic. The temperature control body housing 100 mechanically fixes the copper structures 102w. By means of the fluid conduit 1302, thermal decoupling is implemented between the high power density and high temperature tolerant GPU 1528 and the temperature sensitive RAM modules.

In operation, the copper structures (b) are thermally coupled to the voltage converters (VRM), the copper structures (c) are thermally coupled to the 1528 GPU, and the copper structures (d) are thermally coupled to the RAM modules.

Therefore, a thermal influence of the temperature-sensitive RAM modules is inhibited by the GPU 1528. The same mechanism is used for thermal decoupling between power-dense voltage converters (operation at a high temperature level) and the temperature-sensitive RAM modules. All areas of the temperature control module that are not used for active temperature control can, for example, be made of plastic with low thermal conductivity. This leads to low indirect heat transfer between fluid and ambient areas, resulting in high efficiency of the temperature control module.

The temperature control module 1400 further comprises a fluid inlet 106a and fluid outlet 106b, which are provided by means of openings in the fluid conduit.

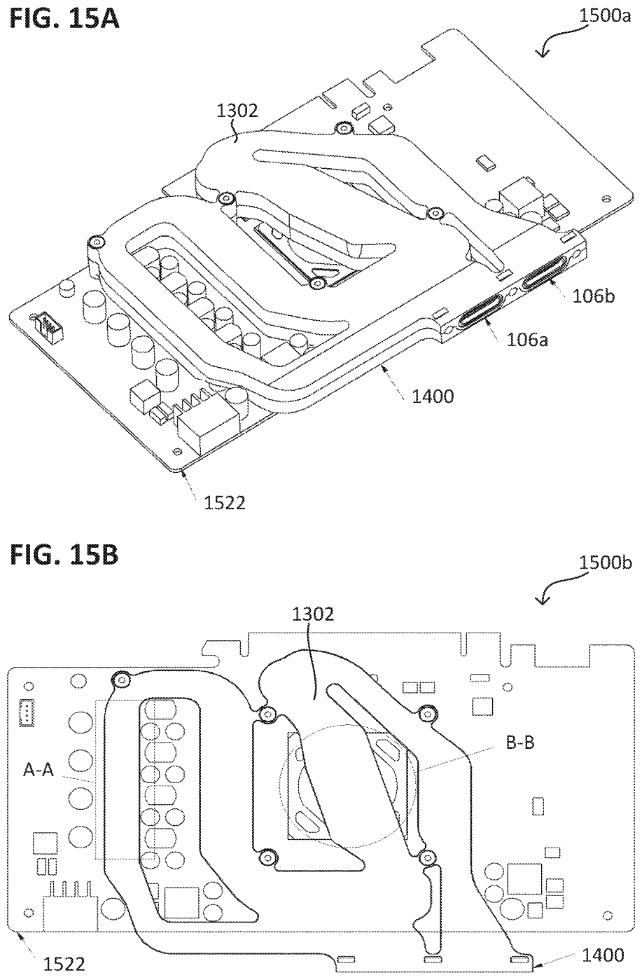

FIG. 15A illustrates an electrical device 1300 according to various embodiments, which includes the temperature control module 1500 and a circuit board 1522, in a schematic perspective view 1500 from above, and FIG. 15B illustrates the temperature control module 1500 in a schematic plan view 1500b from above. The temperature control module 1500 may be mounted on the circuit board 1522 of an electrical component (e.g., a graphics card).

According to various embodiments, only components of the electrical component that are to be temperature controlled (e.g., cooled) may be covered by the temperature control module.

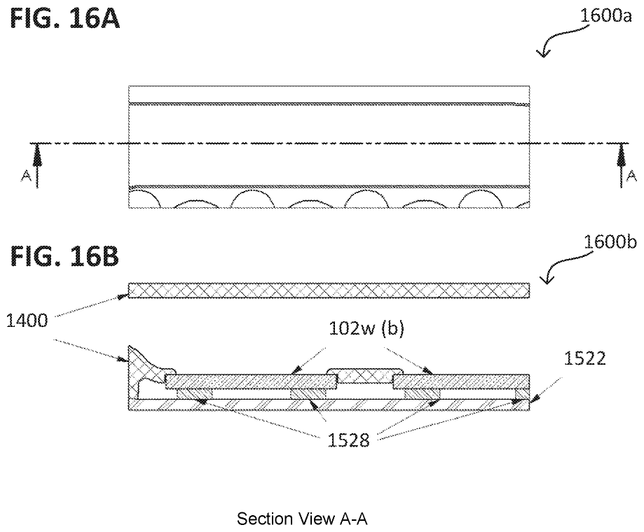

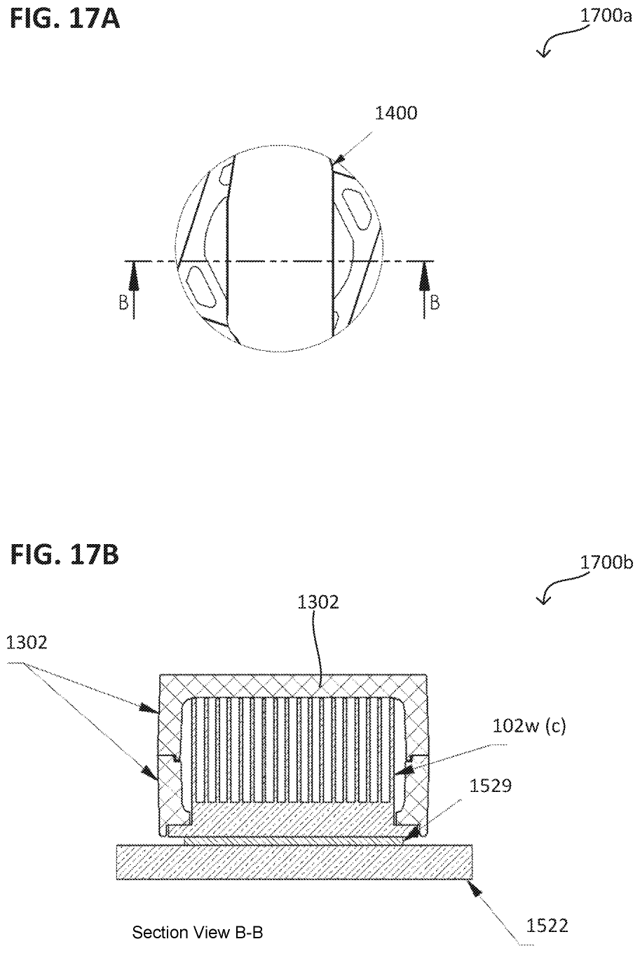

FIG. 16A to FIG. 17B illustrate sectional views A-A and B-B of the electrical device 1300 according to various embodiments in various schematic views 1600a to 1700b (detailed and sectional views).

The detailed and sectional views 1600a, 1600b show the inserted copper structures 102w (b) and (c). These are fixed in the fluid line 1302, for example, by means of an adhesive connection or an end enclosure with plastic. The copper structures 102w lie directly on the components of the component to be temperature controlled (e.g. cooled) or a thermal interface material 902, e.g. thermal conductive paste, thermal conductive pad, can also be set up between them for thermal connection.

The opposite side of the copper structures 102w may be in direct contact with the fluid during operation, or may have fluid flowing directly around them.

This achieves high energy efficiency of the temperature control module by providing a fluid line 1302 thermally insulated by means of a low thermal conductivity plastic. This further achieves an optimal individual component temperature by thermal decoupling of the components and temperature control as required by individual thermal connection. This further achieves minimization of the risk of electrical short circuits through the use of electrically insulating material between the thermal functional surfaces 102w.

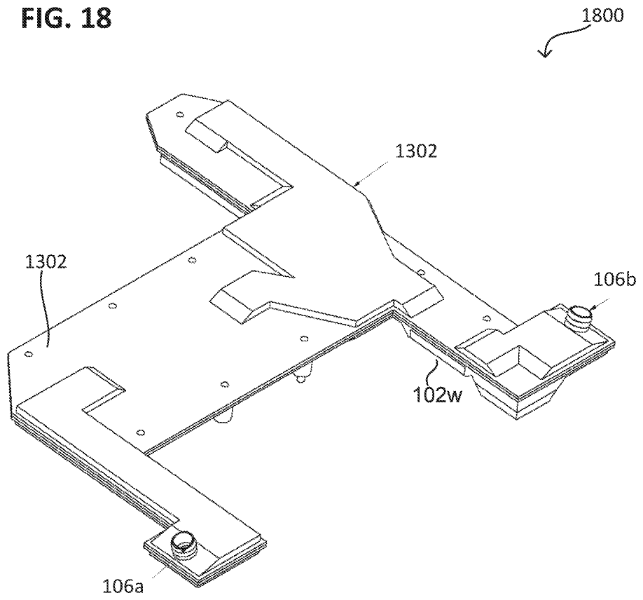

FIG. 18 illustrates a temperature control module 1400 according to various embodiments 1800 in a schematic perspective view.

The temperature control module 1400 according to embodiments 1800 achieves temperature control (e.g., cooling) of a motherboard (e.g., server motherboard). The motherboard has components with different thermal performance or power density and temperature compatibility, which consequently have different requirements for their temperature control.

Examples of components that require active temperature control include: Central processing unit (CPU), which is a component with high thermal power density and high temperature tolerance; voltage converter, which is a component with medium thermal power density and high temperature tolerance; communication processor, which is a component with low thermal power density and low temperature tolerance.

The basic structure of the water temperature control system 1400 comprises a fluid conduit 1302 made of plastic (which has a low thermal conductivity). The connection of voltage converters and communication chips is provided by means of a plurality of heat output receiving surfaces 102w made of thermally conductive plastic (which has a medium thermal conductivity). Thermal connection of the CPU is provided by means of a heat output receiving surface 102w made of copper (which has high thermal conductivity).

The temperature control module 1400 according to various embodiments 1800 achieves high energy efficiency by using a thermally insulated fluid line made of low thermal conductivity plastic; further achieves optimal individual component temperature by thermally decoupling the components and controlling temperature as needed by individual thermal connection; further achieves minimizing the risk of electrical short circuits by using electrically insulating material between the thermal functional surfaces 102w.

In one example according to various embodiments, the basic structure of the temperature control module 1400 comprises a fluid line 1302 made of plastic 1 (i.e., with low thermal conductivity). The fluid inlet 106a and the fluid outlet 106b are integrated in the fluid line 1302.

The connection of voltage converters and communication chips is provided by means of functional areas 102w made of thermally conductive plastic (e) (i.e. having an average thermal conductivity).

The CPU is thermally connected by means of a functional surface 102w made of a copper structure (f) (i.e. having a high thermal conductivity).

The copper structures can be in direct contact with the component 1515 to be temperature controlled (e.g., cooled), or a thermal conductive material 902, e.g., thermal conductive paste, thermal conductive pad, can also be set up between them for thermal connection. The opposite side of the copper structures 102w may be in direct contact with the fluid during operation, or may have fluid flowing directly around them.

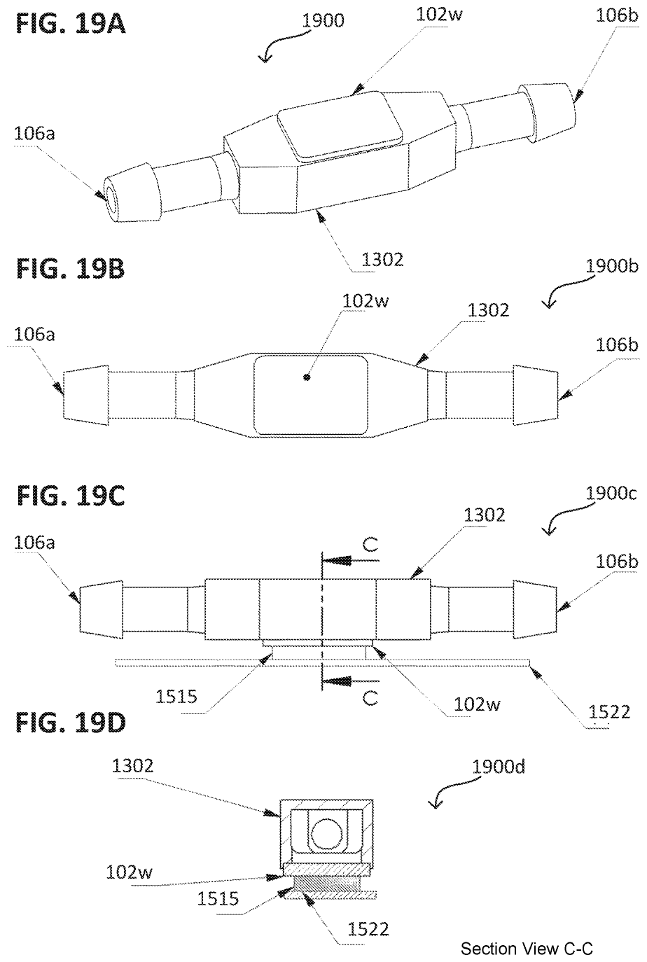

FIG. 19A illustrates a temperature control module 1400 according to various embodiments 1900 in a schematic perspective view, and FIGS. 19B through 19D illustrate the temperature control module 1400 in additional schematic views. The temperature control module 1400 according to various embodiments 1900 facilitates temperature control (e.g., cooling) of peripheral electronic components and need not necessarily include multiple functional areas 102w. The fluid conduit 1302 may be provided in the form of a housing in which the functional surface(s) 102w are embedded.

The temperature control module 1400 includes the fluid conduit 1302 (formed of a plastic), which includes a fluid inlet 106a and fluid outlet 106b. The thermal function surface 102w may be provided using a flat copper structure.

The temperature control module 1400 may be or may be mounted on a printed circuit board 1522 having a chip 1515, or electronic component 1515, to be temperature controlled (e.g., cooled). The copper structure may be attached by means of bonding or font-side wrapping through the plastic of the fluid conduit 1302. The copper structure may rest directly on the component 1515 to be temperature controlled (e.g., cooled), or a thermal conductive material 902, e.g., thermal conductive paste, thermal conductive pad, may be set up between them for thermal connection.

The opposite side of the copper structures 102w may be in direct contact with the fluid during operation, or may have fluid flowing directly around them.

The temperature control module 1400 achieves higher energy efficiency, for example, when the thermally insulated fluid line 1302 is provided in low thermal conductivity plastic.

The temperature control module 1400 achieves minimization of the potential for electrical short circuits through the use of electrically insulating material between for the fluid conduit 1302.

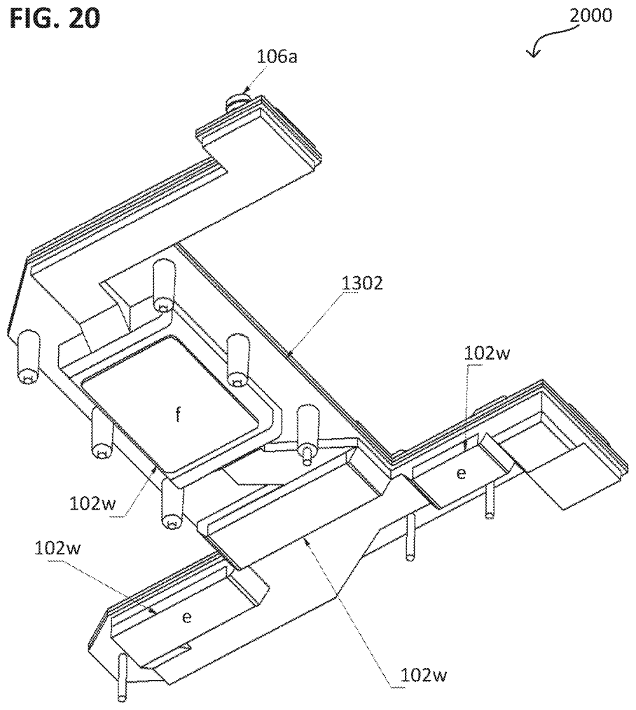

FIG. 20 illustrates a temperature control module 1400 according to various embodiments 2000 in a schematic perspective view.

FIG. 21 illustrates a temperature control body housing 100 according to various embodiments 2100 in a schematic top view or cross-sectional view. The temperature control body housing has: a monolithic housing middle portion 102, a first housing end cap 104a, and a second housing end cap 104b.

The first housing end cap 104a includes the first fluid port 106a and the second fluid port 106b. The housing middle portion 102 is penetrated by one or more than one pair of fluid channels 102k (formed from two fluid ports 102k arranged side by side), each pair of fluid channels 102k fluidly connecting the first fluid port 106a and the second fluid port 106b, e.g., through the second housing end cap 104b (e.g., the cavity 108h thereof).

For example, the first housing end cap 104a may include a partition 108t disposed between (e.g., spatially separating) the first fluid port 106a and the second fluid port 106b and/or contacting the housing middle portion 102. For example, the first housing end cap 104a may include two cavities 108h (separated from each other by the partition), a first cavity 108h of which fluidly connects the first fluid port 106a to the first fluid channel of the pair of fluid channels 102k, and a second cavity 108h of which fluidly connects the second fluid port 106b to the second fluid channel of the pair of fluid channels 102k.

The or each pair of fluid channels 102k may provide a redirection of the flow path 101f within the temperature control body 100, for example within the second housing end cap 104b. In other words, the fluid channels of the pair of fluid channels 102k may differ from each other in the provided flow direction 101f. The flow path 101f may extend through the second housing end cap 104b, for example.

Similar to the foregoing, each fluid canal of the pair of fluid canals 102k extends from a first side 102a (e.g., front-side) of the housing middle portion 102 to a second side 102b (e.g., front-side) of the housing middle portion 102 through the housing middle portion 102 (along direction 101).

What is described herein for the monolithic housing middle portion may apply by analogy to a multi-part housing middle portion having, for example, two or more housing middle portion components (e.g., half-shells) or formed therefrom, wherein the housing end caps are not mandatory, e.g., when the fluid ports are integrated into the half-shells. The one or more than one heat transferring surface of the housing middle portion may optionally be of a different material as supporting structure of the housing middle portion.

Each of the two housing middle portion components may, for example, be an extrusion product, have or be formed from aluminum, and/or have or be formed from plastic.

It may be understood that, as an alternative to the housing end caps described herein, each housing end cap having one fluid port, the two housing end caps may be used, of which (e.g., only) the first housing end cap has two fluid ports (and, e.g., the second housing end cap has fewer or no fluid ports).

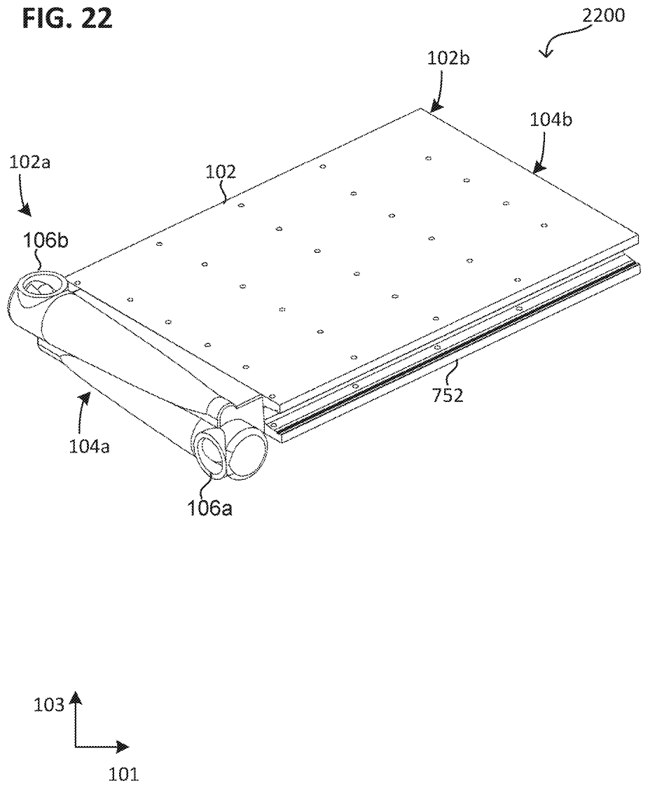

FIG. 22 illustrates a temperature control body housing 100 according to various embodiments 2200 in a schematic perspective view. The temperature control body housing has: a housing middle portion 102, a first housing end cap 104a, and a second housing end cap 104b (hidden in figure). As shown, the second housing end cap 104b does not necessarily have to have a cavity, for example, if it does not have a fluid port. For example, the second housing end cap 104b may comprise or be formed from a plate that closes the second side 102b of the housing middle portion 102 (see, for example, FIG. 28). More generally, the second housing end cap 104b may comprise or be formed from, for example, one or more than one plug that may close (e.g., fluid-tightly) the second side 102b of the housing middle portion 102.

For example, the second housing end cap 104b (e.g., the plug) may be welded or bonded to the housing middle portion 102.

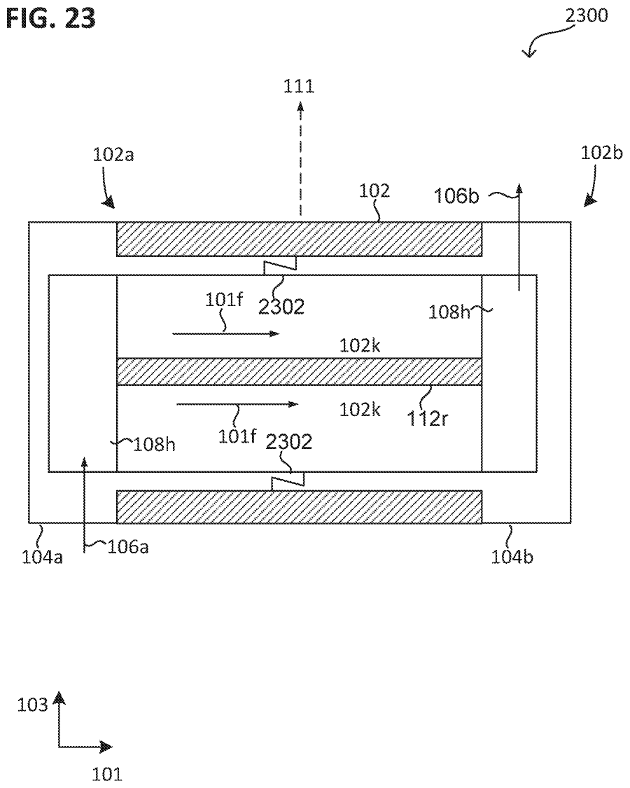

FIG. 23 illustrates a temperature control body housing 100 according to various embodiments 2300 in a schematic top view or cross-sectional view. As mentioned above, two or more housing components may be positively connected to each other, e.g., by means of screwing, riveting, interlocking, e.g., by means of interlocking elements (also referred to as latching elements) and/or by means of other positive locking elements. Alternatively or additionally, two or more housing components can be joined by material, e.g. by bonding, welding, soldering, overmolding with plastic, friction welding.

As shown, the two housing end caps 104a, 104b may be positively connected by means of latching elements 2302 as exemplary positive locking elements. It may be understood that other positive locking elements may be used alternatively or in addition to the latching elements 2302, such as screws or rivets, and/or a fabric joint. The positive locking elements provide that the two housing end caps 104a, 104b are releasably connected to each other and/or to the housing middle portion 102. For example, the positive locking elements 2302 may be configured to non-destructively and/or reversibly make and/or break the connection.

As shown, the two housing end caps 104a, 104b (e.g., their form-fitting elements 2302) may extend into the housing middle portion 102. This facilitates the releasable connection. The same may apply by analogy if the form-fitting elements 2302 are disposed outside the housing middle portion 102.

More generally, one or more than one housing end cap of the two housing end caps 104a, 104b may extend into or through the housing middle portion 102.

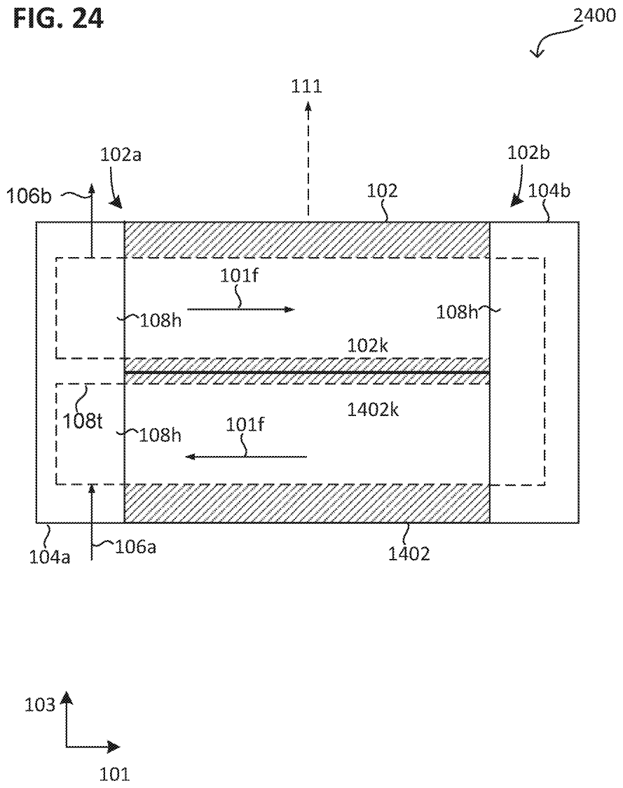

FIG. 24 illustrates a temperature control body housing 100 according to various embodiments 2400 in a schematic top view or cross-sectional view. The temperature control body housing comprises: a first monolithic housing middle portion 102 penetrated by one or more than a first fluid canal 102k, and a second monolithic housing middle portion 1402 (also referred to as an additional housing middle portion) penetrated by one or more than a second fluid canal 1402k, first housing end cap 104a, and second housing end cap 104b. The first housing end cap 104a may include the first fluid port 106a. Either the first housing end cap 104a (as shown) or it may be the second housing end cap 104b that includes the second fluid port 106b. The first fluid port 106a and the second fluid port 106b may be fluidly connected to each other by means of the one or more than one first fluid canal 102k and/or by means of the one or more than one second fluid canal 1402k. For example, the flow path 101f may extend from the first fluid port 106a through the one or more than one first fluid port 102k, thereafter or in parallel thereto through the one or more than one second fluid port 1402k, to the second fluid port 106b.

More generally, the temperature control body housing 100 may include the housing middle portion 102 and additionally one or more than one optional housing middle portion 1402, which are coupled together and/or fluidly coupled together by means of the first housing end cap 104a and/or by means of the second housing end cap 104b. For example, the housing middle portion 102 and any additional housing middle portion 1402 may be covered together on their first side 102a by means of the first housing end cap 104a and may be covered together on their second side 102b by means of the second housing end cap 104b.

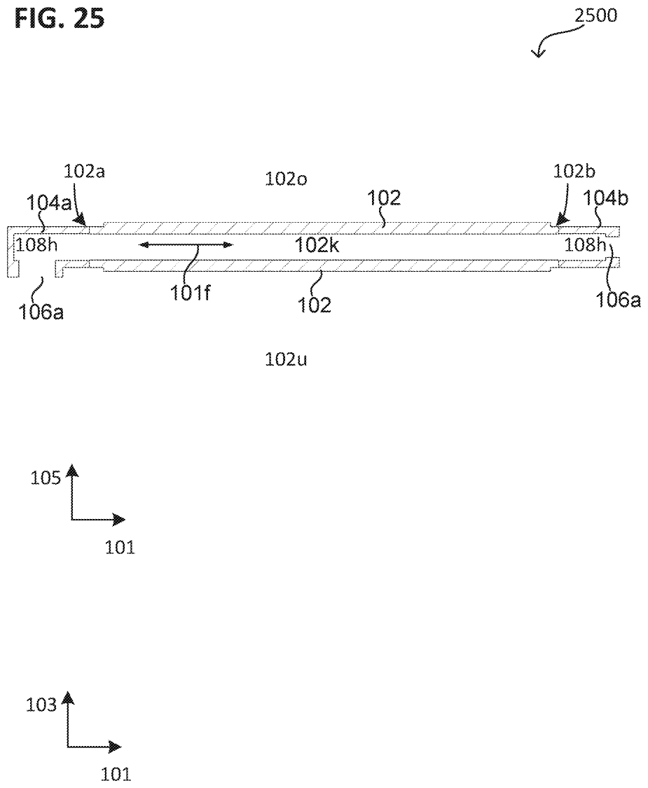

FIG. 25 illustrates a temperature control body housing 100 according to various embodiments 2500 in a schematic cross-sectional view. The housing middle portion may be monolithic or multi-piece. As shown, the cavity 108h of each housing end cap 104a, 104b may be adjacent to, e.g., continuing each fluid canal 102k.

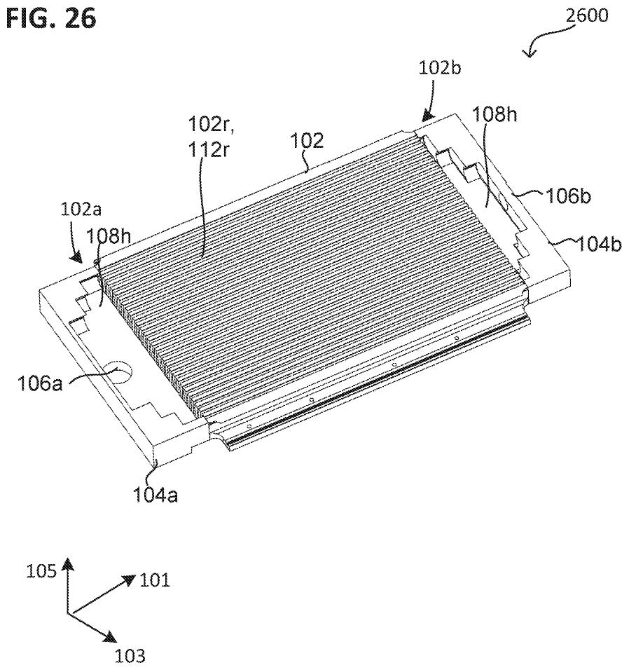

FIG. 26 illustrates a temperature control body housing 100 according to various embodiments 2600 in a schematic perspective view. As shown, a plurality of temperature control fins 102r, 112r (of a first type or a second type) may extend parallel to each other from the first side to the second side. For example, the temperature controlling fins 102r, 112r may be comb-shaped.

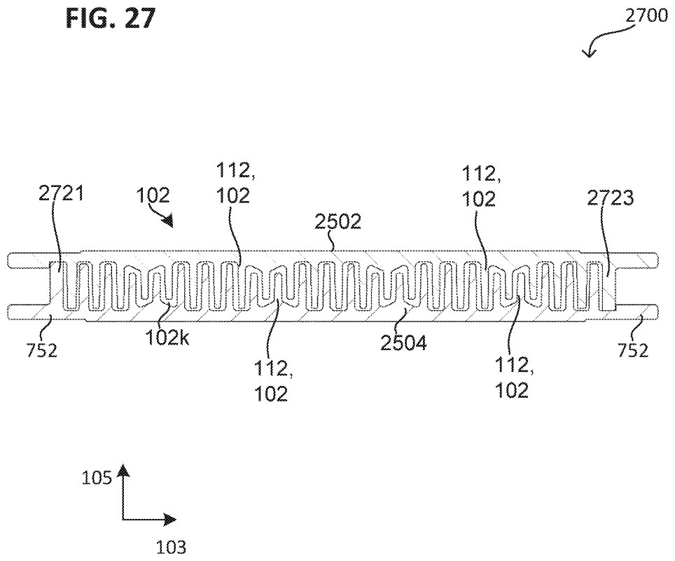

FIG. 27 illustrates a temperature control body housing 100 according to various embodiments 2700 in a schematic cross-sectional view (e.g., looking along the direction of flow). The temperature control body housing 100 may include a housing middle portion 102 that is multi-part (also referred to as a multi-part housing middle portion 102), i.e., that includes a plurality of separate components 2502, 2504. Each of the components 2502, 2504 (also referred to as housing middle portion components) may include one or more than one temperature control fin 102r, 112r (first type or second type).

For example, the first housing middle portion 2502 may be a cover and the second housing middle portion 2502 may be a tray. Alternatively or additionally, both housing middle portion components 2502, 2504 may be stranded, e.g., differing in shape and/or profile.

Alternatively, both housing middle portion components may have the same shape and/or profile (and may both be stranded, for example). This achieves that the structure of the housing middle portion 102 is simplified. Then, for example, the first housing middle portion component 2502 may provide the right outer wall 2723 of the housing middle portion 102 and the second housing middle portion component 2504 may provide the left outer wall 2721 of the housing middle portion 102. The one or more than one fluid canal 102k may be disposed between the outer walls 2721, 2723.

Each of the two housing middle portion components 2502, 2504 may, for example, be an extrusion product, comprise (or be formed from) aluminum, and/or comprise (or be formed from) plastic.

As shown, the temperature control fins 102r, 112r (first type or second type) may engage one another. In other words, a temperature control fin 102r, 112r of the first housing middle portion component 2502 may engage between two temperature control fins 102r, 112r of the second housing middle portion component 2504 or vice versa.

As shown, immediately adjacent temperature controlling fins 102r, 112r may differ from one another, for example, in shape, thickness, width, and/or height.

FIG. 28 illustrates a temperature control body housing 100 according to various embodiments 2800 in a schematic top view or cross-sectional view. The temperature control body housing 100 comprises: a monolithic or multi-part housing middle portion 102, a first housing end cap 104a, and a second housing end cap 104b.

The first housing end cap 104a includes the first fluid port 106a and the second fluid port 106b (not visible in the view). The housing middle portion 102 is penetrated by a plurality of pairs 2802 of fluid channels 102k (formed from two fluid ports 102k arranged side by side), each pair of fluid channels 102k fluidly connecting the first fluid port 106a and the second fluid port 106b. The fluid channels 102k of a pair may be interconnected at the second housing end cap 104b (e.g., still within the housing middle portion 102). To this end, for example, each second temperature control fin may be formed shorter (i.e., retracted) or include an opening. This achieves that the second housing end cap 104b can have a planar surface that covers each pair 2802 (e.g., at their juncture).

This design reduces the complexity of the temperature control body housing 100.

In the following, various examples are described that relate to what has been described above and what is shown in the figures.

Example 1 is a temperature control body housing comprising: a monolithic housing middle portion penetrated by one or more than one fluid canal, a first housing end cap, and a second housing end cap between which the housing middle portion is disposed; wherein the first housing end cap has a first fluid port and either the first housing end cap or the second housing end cap has a second fluid port, and wherein the first fluid port and the second fluid port are fluidly connected to each other by means of the one or more than one fluid canal (e.g., providing the shortest connecting path(s) therebetween).

The temperature control body housing according to Example 1 may optionally further comprise each fluid canal being completely bounded on four sides by means of corresponding walls that are monolithically connected to outer walls of the housing middle portion. For illustrative purposes, each fluid canal may be surrounded on four sides by the housing middle portion (e.g., by a material of the housing middle portion).

Example 2 is a temperature control body housing comprising: a multi-piece housing middle portion penetrated by one or more than one fluid canal, a first housing end cap, and a second housing end cap between which the housing middle portion is disposed; wherein the first housing end cap has a first fluid port and either the first housing end cap or the second housing end cap has a second fluid port, and wherein the first fluid port and the second fluid port are fluidly connected to each other by means of the one or more than one fluid canal (e.g., providing the shortest connecting path(s) therebetween).

Example 3 is the temperature control body housing according to example 1 or 2, wherein the first housing end cap and/or the second housing end cap comprise a plastic or are formed from the plastic.

Example 4 is the temperature control body housing according to any one of Examples 1 to 3, wherein the housing middle portion comprises an extrusion product or is formed from an extrusion product.

Example 5 is the temperature control body housing according to any of Examples 1 to 4, wherein the housing middle portion comprises or is formed from a housing frame and/or hollow section.

Example 6 is the temperature control body housing according to any one of examples 1 to 5, wherein the housing middle portion is stranded.

Example 7 is the temperature control body housing according to any one of examples 1 to 6, further comprising: a fluid tight connection between the housing middle portion and the first housing end cap and/or between the housing middle portion and the second housing end cap.

Example 8 is the temperature control body housing according to any of Examples 1 to 7, wherein the housing middle portion has two mutually parallel end faces between which the one or more than one fluid canal extends.

Example 9 is the temperature control body housing according to any of examples 1 to 8, wherein the housing middle portion has two mutually parallel end faces which are profiled and/or structured (e.g. having a groove and/or a bead profiling).

Example 10 is the temperature control body housing according to any one of examples 1 to 9, further comprising: a seal by means of which the housing middle portion is fluid-tightly connected to the first housing end cap and the second housing end cap, respectively.

Example 11 is the temperature control body housing according to any one of examples 1 to 10, wherein the housing middle portion has a greater thermal conductivity than the first housing end cap and/or the second housing end cap.

Example 12 is the temperature control body housing according to any of examples 1 to 11, wherein the housing middle portion and the first housing end cap and/or the second housing end cap differ from each other in chemical composition and/or in a weight percentage of metallic material.

Example 13 is the temperature control body housing according to any of Examples 1 to 12, wherein the housing middle portion comprises and/or is formed from a metal (e.g., copper and/or aluminum), a ceramic, or a glass.

Example 14 is the temperature control body housing according to any of Examples 1 to 13, wherein the housing middle portion has substantially the same coefficient of expansion as the first housing end cap and/or as the second housing end cap (i.e., a relative deviation of less than 25%, 10%, or 5%).

Example 15 is the temperature control body housing according to any one of examples 1 to 14, wherein the first housing end cap and the second housing end cap are configured to be substantially identical in shape and/or mirror symmetrical to each other.

Example 16 is the temperature control body housing according to any of examples 1 to 15, wherein the housing middle portion includes a first temperature control fin (e.g., cooling fin) extending into the fluid canal. Example 17 is the temperature control body housing of Example 16, wherein the first temperature control fin (e.g., cooling fin) has an asymmetric contour (e.g., an asymmetric profile).

Example 18 is the temperature control body housing of example 17, wherein the first temperature control fin (e.g., cooling fin) has a first side surface and a second side surface (e.g., opposing each other) that are adjacent to the fluid canal, the first side surface having a greater surface area and/or greater extent than the second side surface.

Example 19 is the temperature control body housing according to any one of examples 1 to 18, wherein the housing middle portion comprises two fluid channels immediately adjacent to each other and further comprises a second temperature control fin (e.g. cooling fin) separating the two adjacent fluid channels from each other, wherein, for example, the second temperature control fin (e.g. cooling fin) is coupled to an upper side (e.g. a first heat output receiving surface on the upper side) and a lower side (e.g. a second heat output receiving surface on the lower side) of the.

Example 20 is the temperature control body housing of Example 19, wherein the second temperature control fin (e.g., cooling fin) has an asymmetric contour (e.g., an asymmetric profile).

Example 21 is the temperature control body housing of example 20, wherein the second temperature control fin (e.g., cooling fin) has a first side surface adjacent one of the two immediately adjacent fluid canals, the second temperature control fin (e.g., cooling fin) has a second side surface adjacent the other of the two immediately adjacent fluid canals, the first side surface having a greater surface area and/or greater extent than the second side surface.

Example 22 is the temperature control body housing according to any one of examples 1 to 21, wherein the housing middle portion has a plurality of temperature control fins (e.g., cooling fins) extending along the same direction with an extension into the one or more than one fluid canal, the plurality of temperature control fins (e.g., cooling fins) differing in extension from each other.

Example 23 is the temperature control body housing according to any one of examples 1 to 22, wherein the housing middle portion comprises two immediately adjacent fluid canals having facing sides, the facing sides differing from each other in a surface area and/or extent.

Example 24 is the temperature control body housing according to any one of examples 1 to 23, wherein the housing middle portion has at least two fluid canals having a cross-sectional area along the same plane in which the two fluid canals differ from each other.

Example 25 is the temperature control body housing according to any of Examples 1 to 24, wherein the multi-part housing middle portion comprises (e.g. exactly) two components (e.g. two extrusions) which when joined together provide (e.g. bound) the one or more than one fluid canal, the components being, for example, in the form of (e.g. profiled) half shells.

Example 26 is the temperature control body housing of Example 25, wherein: the two components differ in material, and/or wherein at least one of the two components comprises a plurality of different materials (e.g., a plastic with metal parts inserted); and/or wherein one or more than one component of the two components is monolithic; and/or wherein the two components are mated together; and/or wherein one or more than one component of the two components comprises or is formed from a linear profile; and/or wherein the two components comprise the same number of temperature control fins; and/or wherein the two components comprise the same (e.g., asymmetric) profile.

Example 27 is the temperature control body housing according to any one of examples 1 to 26, further comprising: a (e.g. thermoplastic or viscous) heat conductive material (also referred to as heat conductive substance) arranged on a heat output receiving surface of the housing middle portion, wherein the heat conductive material is provided e.g. by means of a layer, wherein the layer e.g. comprises a plurality of regions differing from each other, e.g., in a thickness and/or in a thermal conductivity, wherein the heat conducting material for example has a greater (plastic and/or elastic) deformability (e.g. elasticity and/or plasticity) than the housing middle portion.

Example 28 is the temperature control body housing of example 27, wherein a heat output absorption of the heat output receiving surface has a first slope during operation of the temperature control body housing; and wherein a thermal resistance of the heat conductive material has a second slope directed along the first slope of the heat output absorption such that the first slope and the second slope at least partially compensate.

Example 29 is the temperature control body housing according to any one of examples 1 to 28, wherein the first housing end cap and the second housing end cap are releasably connected to each other and/or to the housing middle portion (i.e., these provide a releasable connection), for example when joined together.

Example 30 is the temperature control body housing according to any one of examples 1 to 29, wherein the first housing end cap or the second housing end cap are releasably connected to the housing middle portion (i.e., these provide a releasable connection), for example when joined together.

Example 31 is the temperature control body housing according to any one of examples 1 to 30, wherein the first housing end cap and/or the second housing end cap extend into or through the housing middle portion.

Example 32 is the temperature control body housing according to any of Examples 1 to 31, wherein the first housing end cap and the second housing end cap differ from each other in the number of their fluid ports and/or in the orientation of their fluid ports.

Example 33 is the temperature control body housing according to any of Examples 1 to 32, wherein the first housing end cap and the second housing end cap have the same number of fluid ports and/or the same orientation of their fluid ports.

Example 34 is the temperature control body housing according to any one of examples 1 to 33, wherein the housing middle portion is disposed between the first housing end cap and the second housing end cap.

Example 35 is the temperature control body housing according to any one of examples 1 to 34, further comprising: an additional (e.g., monolithic) housing middle portion penetrated by one or more than one additional fluid port, wherein the first fluid port and the second fluid port are fluidly connected to each other by means of the one or more than one additional fluid port.

Example 36 is the temperature control body housing according to any of Examples 1 to 35, wherein the housing middle portion has one or more than one planar outer surface (providing, for example, a heat output receiving surface).

Example 37 is a cooling arrangement, comprising: a temperature control body housing according to any of examples 1 to 36; and a fluid supply coupled to the two fluid ports of the temperature control body housing and adapted to provide fluid flow through the temperature control body housing.

Example 38 is a component assembly (e.g., electrical device) comprising: an electrical component (e.g., a processor), and a temperature control body housing according to any one of examples 1 to 36 disposed on the electrical component (e.g., the processor), wherein, for example, between the electrical component (e.g., the processor) and the housing middle portion is disposed the thermal conductive material.

Example 39 is using a temperature control body housing according to any of Examples 1 to 36 to temperature control (e.g., cool) an electrical component (e.g., a processor).

Example 40 is a temperature control module comprising: a fluid conduit having a first fluid port and a second fluid port; one or more than one (e.g., metallic) temperature control element (e.g., a (e.g., a plurality of temperature control elements); e.g., embedded in the fluid conduit; e.g., the plurality of temperature control elements being spaced apart from each other by the fluid conduit and/or fluidly connected to each other by the fluid conduit; e.g., each temperature control element having greater thermal conductivity and/or electrical conductivity than the fluid conduit; wherein, for example, the plurality of temperature control elements differ from each other in thermal conductivity, wherein, for example, the fluid conduit is formed of one or more than one injection molded product, wherein, for example, the fluid conduit comprises a fluid canal (viz. the interior of the fluid conduit) fluidly connecting the first fluid port and the second fluid port and being adjacent to each temperature control element; wherein, for example, each temperature control element has an (e.g., for example, each temperature control element having an outer surface (e.g., planar) projecting, for example, from the fluid conduit, each temperature control element comprising, for example, a temperature control body or formed therefrom; for example, each temperature control element comprising one or more than one cooling fin, for example, at least one temperature control element comprising, or formed from, a metal; for example, the fluid conduit comprising, or formed from, a polymer (e.g., a plastic).

Example 40b is a temperature control module comprising: a fluid conduit having a first fluid port and a second fluid port; a plurality of temperature control elements embedded in the fluid conduit such that they are thermally isolated from one another; wherein the fluid conduit is formed from one or more than one injection molded product.

The use of injection molding technology for manufacturing allows the temperature control elements to be easily embedded so that they are thermally insulated from each other, as they are each completely enclosed with plastic (which has low thermal conductivity compared to metal) on their end faces.

Example 40c is a temperature control module comprising: a fluid conduit having a first fluid port and a second fluid port; one or more than one temperature control element (102w) positively embedded in the fluid conduit (1302); wherein the fluid conduit is formed from one or more than one injection molded product.

Example 40d is a temperature control module, comprising: a fluid conduit having a first fluid port and a second fluid port; one or more than one temperature control element (102w) embedded in the fluid conduit (1302) in a form-fit or substance-fit manner; wherein the fluid conduit is formed from one or more than one injection molded product.

The form-fit or material-fit connection can be carried out, for example, by means of overmolding of the one or more temperature controlling elements (possibly with prior surface treatment) and/or by means of assembly with locking. In this configuration, an additional sealing element (e.g., a ring seal, an O-Ring) can optionally be -used. As an example, the material connection can be made by means of a plasma surface treatment of the one or more temperature control elements (illustratively, the metal inserts) and subsequent overmolding with plastic.

Example 41 is a cooling arrangement, comprising: a temperature control module according to example 40, 40b, 40c, or 40d; and a fluid supply coupled to the two fluid ports of the temperature control module and adapted to provide fluid flow through the fluid line.

Example 42 is a component assembly (e.g., electrical device) comprising: an electrical component (e.g., comprising a circuit board having a plurality of chips), and a temperature control module according to example 40, 40b, 40c, or 40d having a temperature control element disposed on the electrical component (e.g., the plurality of chips), wherein, for example, a thermal conductive material is disposed between the electrical component (e.g., the processor) and the one or more than one temperature control element.

Example 43 is using a temperature control module according to example 40, 40b, 40c, or 40d to temperature control (e.g., cool) an electrical component (e.g., comprising a circuit board having a plurality of chips).

1. A temperature control body housing, comprising:
a monolithic housing middle portion penetrated by one or more than one fluid canal, each fluid canal being completely bounded on four sides by respective walls which are monolithically connected to outer walls of the housing middle portion;
a first housing end cap and a second housing end cap between which the housing middle portion is disposed;
wherein the first housing end cap has a first fluid port and either the first housing cap or the second housing end cap has a second fluid port, and
wherein the first fluid port and the second fluid port are fluidly connected to each other by means of the one or more than one fluid canal.

2. The temperature control body housing of claim 1, wherein the first housing end cap and the second housing end cap comprise plastic or are formed from plastic.

3. The temperature control body housing according to claim 1, wherein the housing middle portion comprises an extrusion product or is formed from an extrusion product.

4. The temperature control body housing according to claim 1, wherein the housing middle portion comprises or is formed from metal, ceramic, or glass.

5. The temperature control body housing according to claim 1, further comprising:
A seal by means of which the housing middle portion is connected to the first housing end cap and the second housing end cap, respectively, in a fluid-tight manner.

6. The temperature control body housing according to claim 1, wherein the housing middle portion has a substantially same coefficient of expansion as the first housing end cap and/or as the second housing end cap.

7. The temperature control body housing according to claim 1, wherein the housing middle portion comprises a first temperature control rib extending into the fluid canal.

8. The temperature control body housing according to claim 7, wherein the first temperature control rib has an asymmetrical contour.

9. The temperature control body housing according to claim 1, wherein the housing middle portion comprises two directly adjacent fluid canals and further comprises a second temperature control rib separating the two adjacent fluid canals from each other.

10. The temperature control body housing according to claim 9, wherein the second temperature control rib has an asymmetrical contour.

11. The temperature control body housing according to claim 1, wherein the housing middle portion comprises a plurality of temperature control fins extending along a same direction with an extension into the one or more than one fluid canal, the plurality of temperature control fins differing in extension from each other.

12. The temperature control body housing according to claim 1, further comprising:
A heat conductive material disposed on a heat output receiving surface of the housing middle portion.

13. The temperature control body housing according to claim 12,
wherein a heat output absorption of the heat output receiving surface has a first slope during operation of the temperature control body housing; and
wherein a thermal resistance of the heat conductive material has a second slope directed along the slope of the heat output absorption, such that the first slope and the second slope at least partially compensate each other.

14. A temperature control assembly comprising:
a monolithic housing middle portion penetrated by one or more than one fluid canal, each fluid canal being completely bounded on four sides by respective walls which are monolithically connected to outer walls of the housing middle portion;
a first housing end cap and a second housing end cap between which the housing middle portion is disposed;
wherein the first housing end cap has a first fluid port and either the first housing cap or the second housing end cap has a second fluid port;
wherein the first fluid port and the second fluid port are fluidly connected to each other by means of the one or more fluid canal; and
a fluid supply coupled to the two fluid ports of the temperature control body housing and adapted to provide fluid flow through the temperature control body housing.

15. (canceled)

16. A temperature control module, comprising:
a monolithic housing middle portion penetrated by one or more than one fluid canal, each fluid canal being completely bounded on four sides by respective walls which are monolithically connected to outer walls of the housing middle portion;
a first housing end cap and a second housing end cap between which the housing middle portion is disposed;
wherein the first housing end cap has a first fluid port and either the first housing cap or the second housing end cap has a second fluid port, and wherein the first fluid port and the second fluid port are fluidly connected to each other by means of the one or more fluid canal; and
one or more than one temperature control elements embedded in the fluid conduit;
wherein the fluid conduit is formed from one or more than one injection molded product.
